(19) United States
(12) Patent Application Publication
(10) Pub. No.: US 2016/0010201 A1
(43) Pub. Date: Jan. 14, 2016

(54) VAPOR DEPOSITION UNIT AND VAPOR DEPOSITION DEVICE

(71) Applicant: SHARP KABUSHIKI KAISHA, Osaka-shi, Osaka (JP)

(72) Inventors: Yuhki KOBAYASHI, Osaka-shi (JP); Shinichi KAWATO, Osaka-shi (JP); Takashi OCHI, Osaka-shi (JP); Masahiro ICHIHARA, Mitsuke-shi (JP); Eiichi MATSUMOTO, Mitsuke-shi (JP)

(73) Assignee: SHARP KABUSHIKI KAISHA, Osaka-shi, Osaka (JP)

(21) Appl. No.: 14/764,127

(22) PCT Filed: Jan. 22, 2014
(86) PCT No.: PCT/JP2014/051269

§ 371 Date: Jul. 28, 2015

(30) Foreign Application Priority Data
Jan. 29, 2013 (JP) 2013-014766

(51) Int. Cl. C23C 14/04; C23C 14/50; C23C 14/24

(52) U.S. Cl. CPC C23C 14/042; C23C 14/24; C23C 14/50

(57) ABSTRACT

A vapor deposition unit includes: a vapor deposition source; a plurality of limiting plate units provided so as to constitute respective of a plurality of stages, the plurality of limiting plate units including at least a first limiting plate unit and a second limiting plate unit; and a vapor deposition mask which are provided in this order, the first limiting plate unit including a plurality of first limiting plates, the second limiting plate unit including a plurality of second limiting plates, and when viewed in a Z axis direction, the second limiting plates extending in a direction intersecting with a Y axis direction.

### CROSS REFERENCE TO RELATED APPLICATIONS

This application is a U.S. National Phase patent application of PCT/JP2014/051269, filed on Jan. 22, 2014, which claims priority to Japanese Application No. 2013-014766, filed on Jan. 29, 2013, each of which is hereby incorporated by reference in the present disclosure in its entirety.

### FIELD OF THE INVENTION

The present invention relates to a vapor deposition unit and a vapor deposition device each for forming, on a film formation target substrate, a vapor-deposited film having a predetermined pattern.

### BACKGROUND OF THE INVENTION

Recent years have witnessed practical use of a flat-panel display in various products and fields. This has led to a demand for a flat-panel display that is larger in size, achieves higher image quality, and consumes less power.

Under such circumstances, great attention has been drawn to an organic EL display device that (i) includes an organic electroluminescence (hereinafter abbreviated to “EL”) element which uses EL of an organic material and that (ii) is an all-solid-state flat-panel display which is excellent in, for example, low-voltage driving, high-speed response, and self-emitting.

An active matrix organic EL display device includes, for example, (i) a substrate made up of members such as a glass substrate and TFTs (thin film transistors) provided to the glass substrate and (ii) thin film organic EL elements provided on the substrate and electrically connected to the TFTs.

A full-color organic EL display device typically includes organic EL elements of red (R), green (G), and blue (B) as sub-pixels aligned on a substrate. The full-color organic EL display device carries out an image display by, with use of TFTs, selectively causing the organic EL elements to each emit light with a desired luminance.

Thus, such an organic EL display device needs to be produced through at least a process that forms, for each organic EL element, a luminescent layer having a predetermined pattern and made of an organic luminescent material which emits light of the above three colors.

Examples of known methods for forming such a luminescent layer having a predetermined pattern encompass a vacuum vapor deposition method, an inkjet method, and a laser transfer method. For example, the vapor deposition method is mainly used in a low-molecular organic EL display device (OLED) to pattern a luminescent layer.

The vacuum vapor deposition method uses a vapor deposition mask (also referred to as a shadow mask) provided with openings having a predetermined pattern. A thin film having a predetermined pattern is formed by vapor-depositing vapor deposition particles (vapor deposition materials, film formation materials) from a vapor deposition source on a vapor deposition target surface through the openings of the vapor deposition mask. In this case, the vapor deposition is carried out for each color of luminescent layers (This is referred to as “selective vapor deposition”).

The vacuum vapor-deposition method is roughly classified into two methods: (i) a method for forming a film by fixing or sequentially moving a film formation target substrate and a vapor-deposition mask so that the film formation target substrate and the vapor-deposition mask are brought into close contact with each other; and (ii) a scanning vapor-deposition method for forming a film while scanning a film formation target substrate and a vapor-deposition mask which are provided so as to be spaced from each other.

The method (i) uses a vapor deposition mask similar in size to a film formation target substrate. However, use of the vapor deposition mask similar in size to the film formation target substrate makes the vapor deposition mask larger in size as the film formation target substrate is made larger in size. Thus, such an increase in size of the film formation target substrate accordingly easily causes a gap between the film formation target substrate and the vapor deposition mask by self-weight bending and extension of the vapor deposition mask. Therefore, according to a large-sized substrate, it is difficult to carry out patterning with high accuracy and positional displacement of vapor deposition and/or color mixture occur(s). This makes it difficult to form a high-definition vapor-deposition pattern.

Further, as the film formation target substrate increases in size, not only the vapor deposition mask but also a frame, for example that holds, for example, the vapor deposition mask is made enormously large in size and weight. Thus, the increase in size of the film formation target substrate makes it difficult to handle, for example, the vapor deposition mask and the frame. This may cause a problem with productivity and/or safety. Further, a vapor deposition device itself and the accompanying devices are also made larger in size and complicated. This makes device design difficult and increases installation cost.

Thus, it is actually impossible to subject a large-sized substrate having a size of, for example, more than 60 inches to selective vapor deposition at a mass production level by the method (i).

In view of the problems, great attention has recently been drawn to a scan vapor deposition method for carrying out vapor deposition while carrying out scanning by use of a vapor deposition mask which is smaller than a film formation target substrate.

According to such a scan vapor deposition method, a band-shaped vapor deposition mask, for example, is used, and that vapor deposition mask is, for example, integrated with a vapor deposition source. Then, vapor deposition particles are vapor-deposited on an entire surface of a film formation target substrate while at least one of (i) the film formation target substrate and (ii) the vapor deposition mask and the vapor deposition source is moved with respect to the other.

Thus, the scan vapor deposition method, which makes it unnecessary to use the vapor deposition mask similar in size to the film formation target substrate, can solve the above problems that uniquely occur when a large-sized vapor deposition mask is used.

Meanwhile, however, according to the scan vapor deposition method, in which at least one of (i) the film formation target substrate and (ii) the vapor deposition mask and the vapor deposition source is moved with respect to the other, a gap is provided between the film formation target substrate and the vapor deposition mask.

According to the vacuum vapor deposition method using a vapor deposition mask, vapor deposition is carried out by heating a vapor deposition material, evaporating or sublimating the vapor deposition material, and injecting (scattering) the evaporated or sublimated vapor deposition material, as vapor deposition particles, from a vapor deposition source. Thus, unless the vapor deposition particles can be properly led to a vapor deposition area which is to be vapor-deposited, a vapor deposition material is attached to an outside of the vapor deposition area, so that a vapor deposition blur (a pattern blur) occurs.

According to the scan vapor deposition method, scanning is carried out while the gap between the film formation target substrate and the vapor deposition mask is maintained. This causes part of vapor deposition particles obliquely passing through an opening of the vapor deposition mask to be attached to the outside of the vapor deposition area (an area facing the opening of the vapor deposition mask), so that the vapor deposition blur easily occurs in a direction perpendicular to a scanning direction.

A luminescent layer, for example, functions as a light emitting area of a pixel. Thus, a vapor deposition blur that extends to a light emitting area of a different color of an adjacent pixel causes color mixture and/or a deterioration in device characteristic. This makes it desirable to make the vapor deposition blur as small as possible.

In view of the problems, there has recently been proposed, as a method for reducing a vapor deposition blur, a method for properly directing vapor deposition particles to a vapor deposition area by increasing directivity of a vapor deposition flow (a flow of the vapor deposition particles) by providing a limiting plate (a control plate) for limiting the vapor deposition flow (e.g., Patent Literature 1).

FIG. 14 is a perspective view schematically illustrating a configuration of a vapor deposition device disclosed in Patent Literature 1.

Patent Literature 1 discloses, for example, that a blocking wall assembly 310 is provided on one side of a vapor deposition source 301, the blocking wall assembly 310 including, as limiting plates, a plurality of blocking walls 311 partitioning a space between the vapor deposition source 301 and a vapor deposition mask 302 into a plurality of vapor deposition spaces. According to Patent Literature 1, since the blocking walls 311 limit a vapor deposition range, it is possible to vapor-deposit a pattern with high definition while preventing spread of a vapor deposition pattern.

### PATENT LITERATURE 1

Japanese Patent Application Publication, Tokukai, No. 2010-270396 A (Publication Date: Dec. 2, 2010)

### SUMMARY OF THE INVENTION

However, a vapor deposition blur cannot be removed by such a method when a vapor deposition speed is high (i.e., when a vapor deposition rate is high).

FIGS. 15A and 15B schematically illustrate a difference in vapor deposition flow due to a difference in vapor deposition speed in a case where a plurality of commonly-used limiting plates 320 are provided between a vapor deposition source 301 and a vapor deposition mask 302 in a direction perpendicular to a scanning direction. FIG. 15A illustrates a case where the vapor deposition speed is relatively low (when a vapor deposition rate is low). FIG. 15B illustrates a case where the vapor deposition speed is relatively high (when the vapor deposition rate is high). FIG. 16 is a substantial part plan view schematically illustrating vapor deposition particles 401 that have passed through a space between the respective limiting plates 320 when the vapor deposition rate is high.

For example, unless a special nozzle is used for an injection hole 301a of the vapor deposition source 301, the vapor deposition particles 401 (vapor deposition flows) injected from the vapor deposition source 301 and then scattered are isotropically distributed.

Thus, even in a case where the limiting plates 320 are provided between the vapor deposition source 301 and the vapor deposition mask 302 as illustrated in FIGS. 15A and 15B, the vapor deposition particles 401 that have passed through the vapor deposition mask 302 at a small angle with respect to a direction (an X axis direction) perpendicular to the scanning direction cause a vapor deposition blur in a vapor-deposited film 402 formed on a film formation target substrate 200.

The limiting plates 320 have a function of improving directivity of the vapor deposition flows by limiting the vapor deposition flows by (i) blocking the vapor deposition particles 401 entering the limiting plates 320 at a small angle with respect to the direction (the X axis direction) perpendicular to the scanning direction and (ii) extracting only a vapor deposition particle 401 entering the limiting plates 320 at a great angle with respect to the direction (the X axis direction) perpendicular to the scanning direction.

When the vapor deposition speed is low (i.e., when the vapor deposition rate is low), the vapor deposition particles 401 that have passed through a limiting plate opening 321 provided between the respective limiting plates 320 pass through the vapor deposition mask 302 while maintaining directivity to some extent (see FIG. 15A). This makes it possible to remove the vapor deposition blur.

Meanwhile, when the vapor deposition rate is high, the vapor deposition particles 401 have high kinetic energy. Thus, as illustrated in FIG. 15B, the vapor deposition particles 401 are highly likely to collide and scatter when the vapor deposition rate is high. As a result, as illustrated in FIG. 16, vapor deposition flows limited (controlled) by the limiting plates 320 are isotropically distributed again after passing through the limiting plate opening 321 (see FIG. 16). This causes the vapor deposition blur.

That is, the conventional limiting plates 320 cannot control vapor deposition flows having high kinetic energy as when the vapor deposition rate is high. This causes the vapor deposition blur.

The vapor deposition blur that is made larger causes, for example, uneven light emission in a pixel and color mixture with respect to an adjacent pixel. This causes a great problem with image quality.

Same applies to the vapor deposition device disclosed in Patent Literature 1. Vapor deposition particles 401 that have passed through the blocking wall assembly 310 at a small angle with respect to the X axis by colliding and scattering when the vapor deposition rate is high pass through the vapor deposition mask 302 while maintaining the small angle with respect to the X axis. Thus, the vapor deposition device disclosed in Patent Literature 1 cannot reduce the vapor deposition blur occurring when the vapor deposition rate is high.

Note that the limiting plates 320 (e.g., blocking walls 311) that have a smaller interval therebetween so as to reduce the vapor deposition blur occurring when the vapor deposition rate is high causes a rapid decline in aperture ratio of the limiting plates 320. This reduces efficiency of utilization of a vapor deposition material.

Meanwhile, in a case where the limiting plates 320 (e.g., barrier walls 311) and the vapor deposition mask 302 are brought closer to each other so as to reduce the vapor deposition blur occurring when the vapor deposition rate is high, the limiting plates 320 have a longer length in a Z axis direction (a direction normal to the film formation target substrate 200).

However, in a case where the limiting plates 320 having a long length in the Z axis direction are used and collision and scattering of the vapor deposition particles 401 occur two or more times, the limiting plates 320 also block vapor deposition components which are not supposed to cause a vapor deposition blur. This results in considerably low material utilization efficiency, a low yield, and considerably low productivity. Further, since the limiting plates 320 increase in weight and thermal expansion amount, vapor deposition blurs vary in width.

The present invention has been made in view of the problems, and an object of the present invention is to provide a vapor deposition unit and a vapor deposition device each of which, by efficiently blocking only a vapor deposition flow causing a vapor deposition blur, allows a reduction in vapor deposition blur without reducing material utilization efficiency.

In order to attain the object, a vapor deposition unit in accordance with an aspect of the present invention includes: a vapor deposition mask; a vapor deposition source for injecting vapor deposition particles toward the vapor deposition mask; and a plurality of limiting plate units provided so as to constitute respective of a plurality of stages, the plurality of limiting plate units including at least a first limiting plate unit and a second limiting plate unit, and the plurality of limiting plate units being provided between the vapor deposition mask and the vapor deposition source and limiting angles at which the vapor deposition particles pass through the plurality of limiting plate units, the first limiting plate unit including a first limiting plate row of a plurality of first limiting plates which, when viewed in a direction perpendicular to a principal surface of the vapor deposition mask, are provided so as to be spaced from each other in a first direction and be parallel to each other, the second limiting plate unit being provided between the first limiting plate unit and the vapor deposition mask and including a plurality of second limiting plates, and when viewed in the direction perpendicular to the principal surface of the vapor deposition mask, the plurality of second limiting plates extending in a direction intersecting with a second direction perpendicular to the first direction.

A vapor deposition device in accordance with an aspect of the present invention includes: the vapor deposition unit recited in any one of claims 1 through 14; and a moving device for, in a state in which the vapor deposition mask of the vapor deposition unit and a film formation target substrate are provided so as to face each other, moving one of the vapor deposition unit and the film formation target substrate with respect to the other so that the second direction is a scanning direction, the vapor deposition mask having a smaller width in the second direction than the film formation target substrate, while carrying out scanning in the second direction, the vapor deposition device vapor-depositing, on the film formation target substrate via (i) the plurality of limiting plate units provided so as to constitute respective of the plurality of stages and (ii) an opening of the vapor deposition mask, the vapor deposition particles injected from the vapor deposition source.

According to an aspect of the present invention, the vapor deposition flows which are made of the vapor deposition particles injected from the vapor deposition source and have an isotropic distribution are controlled so as to have a distribution high in directivity by causing the plurality of first limiting plates 22 to block (capture) vapor deposition components included in the vapor deposition flows and having low directivity. The vapor deposition flows thus controlled and high in vapor deposition speed (i.e., high in vapor deposition rate) have lower directivity after passing through an opening area provided between the respective plurality of first limiting plates. This is because of collision and scattering of the vapor deposition particles due to high kinetic energy of the vapor deposition flows. The vapor deposition flows having lower directivity are controlled so as to have a distribution high in directivity by causing the plurality of second limiting plates to block again the vapor deposition components having low directivity. Thus, the vapor deposition flows pass through the mask opening while maintaining high directivity. This allows a reduction in vapor deposition blur and makes it possible to form a high-definition vapor-deposited film pattern having an extremely small amount of vapor deposition blur.

The vapor deposition unit 1, which includes, on a vapor deposition route, a plurality of limiting plate units provided so as to constitute respective of a plurality of stages can efficiently block, in accordance with a distribution of vapor deposition flows, only a distribution of vapor deposition flows causing a vapor deposition blur. This reduces a material to be wasted on the limiting plates as in the limiting plates having a longer length when viewed in the direction perpendicular to the principal surface of the vapor deposition mask, i.e., the direction normal to the film formation target substrate.

Thus, the vapor deposition unit and the vapor deposition device make it possible to (i) reduce a vapor deposition blur occurring when the vapor deposition rate is high and (ii) further enhance material utilization efficiency as compared with a conventional technique. This allows a higher yield and higher productivity.

### BRIEF DESCRIPTION OF THE DRAWINGS

FIG. 1 is a perspective view schematically illustrating, together with a film formation target substrate, a configuration of a substantial part of a vapor deposition unit of a vapor deposition device in accordance with Embodiment 1.

FIG. 2 is a substantial part plan view schematically illustrating, together with vapor deposition particles that have passed through a space between a respective plurality of first limiting plates when a vapor deposition rate is high, the plurality of first limiting plates and a plurality of second limiting plates of the vapor deposition device in accordance with Embodiment 1 each viewed in a direction perpendicular to a principal surface of a vapor deposition mask.

FIG. 3 is a cross-sectional view illustrating an example of a vapor deposition flow in a case where the first limiting plates are provided via a gap in a Z axis direction so as to constitute respective of two stages.

FIG. 4 is a perspective view schematically illustrating example configurations of a first limiting plate unit and a second limiting plate unit of the vapor deposition device in accordance with Embodiment 1.

FIG. 5 is a perspective view schematically illustrating another example configuration of the second limiting plate unit of the vapor deposition device in accordance with Embodiment 1.

FIG. 6 is a cross-sectional view schematically illustrating a configuration of a substantial part of the vapor deposition device in accordance with Embodiment 1.

FIG. 7 is a substantial part plan view schematically illustrating another configuration of the limiting plate unit in accordance with Embodiment 1.

FIG. 8 is a perspective view schematically illustrating, together with a film formation target substrate, a configuration of a substantial part of a vapor deposition unit of a vapor deposition device in accordance with Embodiment 2.

FIG. 9 is a substantial part plan view schematically illustrating, together with vapor deposition particles that have passed through a space between respective first limiting plates when a vapor deposition rate is high, the first limiting plates and second limiting plates of the vapor deposition device in accordance with Embodiment 2 each viewed in a direction perpendicular to a principal surface of a vapor deposition mask.

FIGS. 10A-10L are substantial part plan views each schematically illustrating another configuration of the limiting plate units in accordance with Embodiment 2.

FIGS. 11A-11C are plan views each showing an example of another pattern of a second limiting plate of the limiting plate units in accordance with Embodiment 2.

FIG. 12 is a perspective view schematically illustrating, together with a film formation target substrate, a configuration of a substantial part of a vapor deposition unit of a vapor deposition device in accordance with Embodiment 3.

FIG. 13 is a substantial part plan view schematically illustrating a configuration of a limiting plate unit in accordance with Embodiment 3.

FIG. 14 is a perspective view schematically illustrating a configuration of a vapor deposition device disclosed in Patent Literature 1.

FIGS. 15A and 15B schematically illustrate a difference in vapor deposition flow due to a difference in vapor deposition speed in a case where a plurality of commonly-used limiting plates are provided between a vapor deposition source and a vapor deposition mask in a direction perpendicular to a scanning direction. FIG. 15A illustrates a case where a vapor deposition rate is low. FIG. 15B illustrates a case where the vapor deposition rate is high.

FIG. 16 is a substantial part plan view schematically illustrating vapor deposition particles that have passed through a space between the respective limiting plates of FIG. 15B when the vapor deposition rate is high.

### DETAILED DESCRIPTION OF THE INVENTION

The following description will discuss embodiments of the present invention in detail.

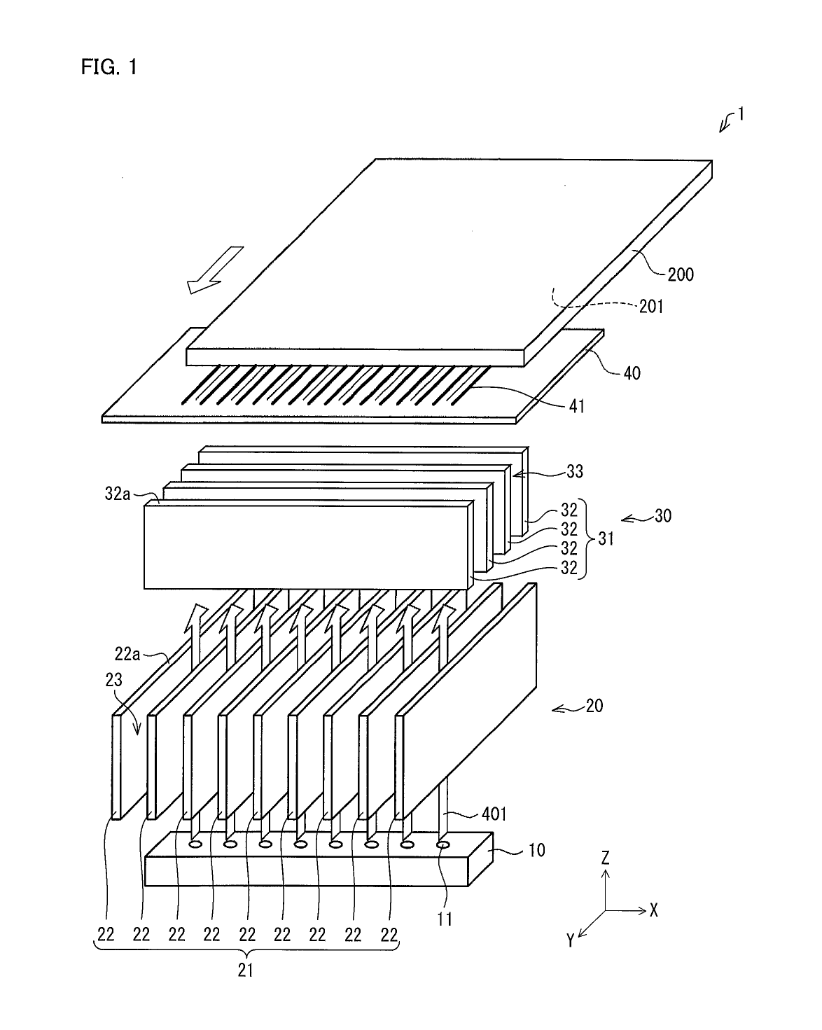

The following description will discuss an embodiment of the present invention with reference to FIGS. 1 through 7.

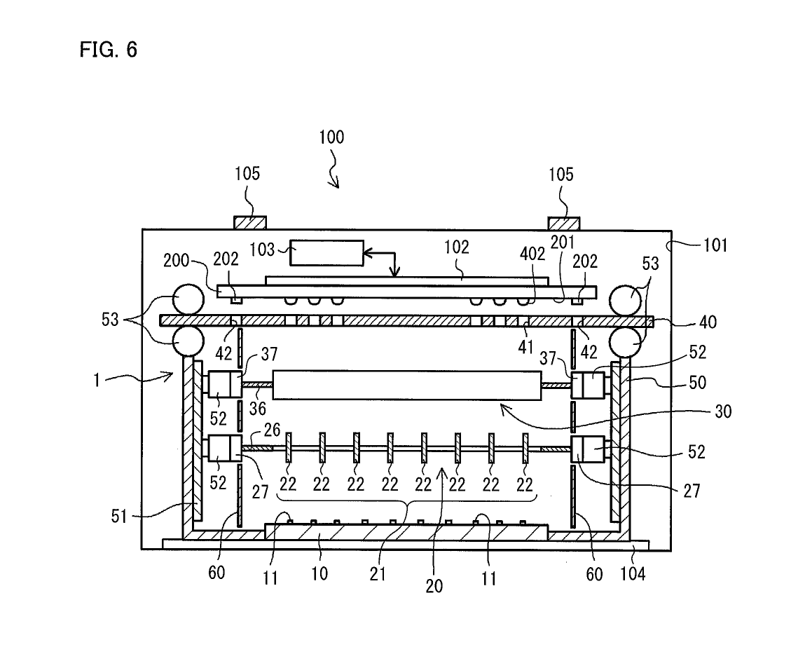

FIG. 1 is a perspective view schematically illustrating, together with a film formation target substrate 200, a configuration of substantial part of a vapor deposition unit 1 of a vapor deposition device 100 (see FIG. 6) in accordance with Embodiment 1.

Note that, for convenience, the following description assumes that (i) a Y axis is a horizontal axis extending in a scanning direction of the film formation target substrate 200, (ii) an X axis is a horizontal axis extending in a direction perpendicular to the scanning direction of the film formation target substrate 200, and (iii) a Z axis is a vertical axis which is perpendicular to each of the X axis and the Y axis, which is a direction normal to a vapor deposition target surface 201 (a film formation target surface) of the film formation target substrate 200, and in which a vapor deposition axis orthogonal to the vapor deposition target surface 201 extends. Note also that, for convenience, the following description assumes that the arrow side in a Z axis direction (upper side in the drawing of FIG. 1) is “an upper side”, unless otherwise particularly mentioned.

As illustrated in FIG. 1, the vapor deposition unit 1 in accordance with Embodiment 1 includes a vapor deposition source 10, a vapor deposition mask 40, and a first limiting plate unit 20 and a second limiting plate unit 30 which are provided between the vapor deposition source 10 and the vapor deposition mask 40 and limit angles at which vapor deposition particles 401 pass through the first limiting plate unit 20 and the second limiting plate unit 30.

The vapor deposition source 10, the first limiting plate unit 20, the second limiting plate unit 30, and the vapor deposition mask 40 are provided in this order from the vapor deposition source 10 side in the Z axis direction so as to, for example, face each other while having a certain gap therebetween (i.e., while being spaced away from each other by a certain gap).

The vapor deposition device 100 is a vapor deposition device using a scanning vapor-deposition method. Thus, according to the vapor deposition device 100, at least one of the film formation target substrate 200 and the vapor deposition unit 1 is moved (scanned) with respect to the other while a certain gap is secured between the vapor deposition mask 40 and the film formation target substrate 200.

This causes a relative position of the vapor deposition source 10, the first limiting plate unit 20, the second limiting plate unit 30, and the vapor deposition mask 40 to be fixed. Thus, the vapor deposition source 10, the first limiting plate unit 20, the second limiting plate unit 30, and the vapor deposition mask 40 (i) can be held by a holding member (not illustrated) such as a single holder (e.g., a holder 50 illustrated in FIG. 6) or (ii) can be integrated with each other.

The vapor deposition source 10 is a container containing therein a vapor deposition material, for example. The vapor deposition source 10 can be a container directly containing therein a vapor deposition material. Alternatively, the vapor deposition source 10 can include a load-lock pipe so that a vapor deposition material is externally supplied to the vapor deposition source 10.

As illustrated in FIG. 1, the vapor deposition source has a quadrilateral shape, for example. The vapor deposition source 10 has a top surface (i.e., a surface facing the first limiting plate unit 20) provided with a plurality of injection holes 11 (through holes, nozzles) from which the vapor deposition particles 401 are injected. The plurality of injection holes 11 are provided at a certain pitch in an X axis direction (a first direction, a direction perpendicular to the scanning direction).

The vapor deposition source 10 generates the vapor deposition particles 401 in a form of gas by heating a vapor deposition material so that the vapor deposition material is evaporated (in a case where the vapor deposition material is a liquid material) or sublimated (in a case where the vapor deposition material is a solid material). The vapor deposition source 10 injects, from the injection holes 11 toward the first limiting plate unit 20, the vapor deposition material in the form of the vapor deposition particles 401 in the form of gas.

FIG. 1 shows, as an example, a case where the vapor deposition source 10 has the plurality of injection holes 11. Note, however, that the number of injection holes 11 is not particularly limited, and the vapor deposition source 10 only needs to have at least one injection hole 11.

Further, the injection holes 11 can be arranged one-dimensionally (i.e., in a linear manner) in the X axis direction as illustrated in FIG. 1 or can be arranged two-dimensionally (i.e., in a planar manner (so as to be tiled)).

The vapor deposition mask 40 is a plate and has a mask surface, which is a principal surface (a surface having a largest area) of the vapor deposition mask 40 and is parallel to an XY plane. Scan vapor deposition is carried out by using, as the vapor deposition mask 40, a vapor deposition mask which is smaller in size at least in a Y axis direction than the film formation target substrate 200.

The vapor deposition mask 40 has the principal surface provided with a plurality of mask openings 41 (openings, through holes) through which the vapor deposition particles 401 pass during vapor deposition. The plurality of mask openings 41 are provided so as to correspond to a pattern of a part of a target vapor deposition area of the film formation target substrate 200 so that the vapor deposition particles 401 are not attached to the other area of the film formation target substrate 200. Only the vapor deposition particles 401 that have passed through the plurality of mask openings 41 reach the film formation target substrate 200, so that a vapor-deposited film 402 (see FIG. 6) having a pattern corresponding to the plurality of mask openings 41 is formed on the film formation target substrate 200.

Note that luminescent layers of an organic EL display device which are made of the vapor deposition material are vapor-deposited for each color of the luminescent layers in an organic EL vapor deposition process.

As described earlier, the first limiting plate unit 20 and the second limiting plate unit 30 are provided, between the vapor deposition source 10 and the vapor deposition mask 40, in this order from the vapor deposition source 10 side in the Z axis direction.

The first limiting plate unit 20 includes a first limiting plate row 21 of a plurality of first limiting plates 22. The second limiting plate unit 30 includes a second limiting plate row 31 of a plurality of second limiting plates 32.

The vapor deposition particles 401 injected from the vapor deposition source 10 pass through a space between the respective plurality of first limiting plates 22 and then pass through a space between the respective plurality of second limiting plates 32. Thereafter, the vapor deposition particles 401 pass through the plurality of mask openings 41 provided on the vapor deposition mask 40, and are then vapor-deposited on the film formation target substrate 200.

The first limiting plate unit 20 selectively captures, in accordance with angles at which the vapor deposition particles 401 have entered the first limiting plate unit 20, the vapor deposition particles 401 that have entered the first limiting plate unit 20. The second limiting plate unit 30 selectively captures, in accordance with angles at which the vapor deposition particles 401 have entered the second limiting plate unit 30, the vapor deposition particles 401 that have entered the second limiting plate unit 30.

By, for example, capturing at least part of the vapor deposition particles 401 that have collided with the plurality of first limiting plates 22, the first limiting plate unit 20 limits movement, in a direction (i.e., the X axis direction and an oblique direction) in which the plurality of first limiting plates 22 are provided, of the vapor deposition particles 401 injected from the vapor deposition source 10.

Meanwhile, by, for example, capturing at least part of the vapor deposition particles 401 that have collided with the plurality of second limiting plates 32, the second limiting plate unit 30 limits movement, in a direction (i.e., the Y axis direction and the oblique direction) in which the plurality of second limiting plates 32 are provided, of the vapor deposition particles 401 that have passed through the space between the respective plurality of first limiting plates 22.

This allows the first limiting plate unit 20 and the second limiting plate unit 30 to limit, within a certain range, angles at which the vapor deposition particles 401 enter the plurality of mask openings 41 of the vapor deposition mask 40, and to prevent the vapor deposition particles 401 from being obliquely attached to the film formation target substrate 200.

According to Embodiment 1, the plurality of first limiting plates 22 are made of respective plate members having an identical size. The plurality of second limiting plates 32 are also made of respective plate members having an identical size. Note, however, that the plurality of first limiting plates 22 do not need to be identical in size to the second limiting plates 32.

The plurality of first limiting plates 22 and the plurality of second limiting plates 32 are provided so as not to be parallel to each other in a single YZ plane. The plurality of first limiting plates 22 and the plurality of second limiting plates 32 extend in different directions when viewed in a direction perpendicular to the principal surface of the vapor deposition mask 40.

The plurality of first limiting plates 22 extend in parallel to the Y axis when viewed in the direction perpendicular to the principal surface of the vapor deposition mask 40. The plurality of first limiting plates 22 are provided in parallel to each other in the X axis direction at equal pitches. According to this, when viewed in the direction (i.e., a direction parallel to the Z axis) perpendicular to the principal surface of the vapor deposition mask 40, a limiting plate opening 23 serving as an opening area is provided between the respective plurality of first limiting plates 22, which are adjacent to each other in the X axis direction.

According to Embodiment 1, the plurality of first limiting plates 22 are provided such that the injection holes 11 of the vapor deposition source 10 correspond to respective limiting plate openings 23. A position in the X axis direction of an injection hole 11 is a middle position in the X axis direction of adjacent ones of the plurality of first limiting plates 22. The limiting plate openings 23 have a pitch that is larger than that of the plurality of mask openings 41. When viewed in the direction perpendicular to the principal surface of the vapor deposition mask 40, the plurality of mask openings 41 are provided between the first limiting plates 22 that are adjacent to each other in the X axis direction.

Meanwhile, the plurality of second limiting plates 32 extend in parallel to the X axis when viewed in the direction perpendicular to the principal surface of the vapor deposition mask 40. The plurality of second limiting plates 32 are provided in parallel to each other in the Y axis direction (a second direction, the scanning direction) at equal pitches. According to this, when viewed in the direction perpendicular to the principal surface of the vapor deposition mask 40, a limiting plate opening 33 serving as an opening area is provided between the respective plurality of second limiting plates 32 that are adjacent to each other in the Y axis direction.

The plurality of first limiting plates 22 each have principal surfaces that are each the YZ plane. Meanwhile, the plurality of second limiting plates 32 each have principal surfaces that are each an XZ plane.

The plurality of first limiting plates 22 and the plurality of second limiting plates 32 are provided so as to be perpendicular to the principal surface of the vapor deposition mask 40. That is, the plurality of first limiting plates 22 and the plurality of second limiting plates 32 are provided so that front and back surfaces, which serve as the principal surfaces, of the plurality of first limiting plates 22 and of the plurality of second limiting plates 32 face in a direction perpendicular to the vapor deposition target surface 201 of the film formation target substrate 200. Thus, the first plurality of limiting plates 22 are provided so that the principal surfaces are adjacent to each other in the X axis direction. The plurality of second limiting plates 32 are provided so that the principal surfaces are adjacent to each other in the Y axis direction.

According to Embodiment 1, the plurality of first limiting plates 22 and the plurality of second limiting plates 32 each have a rectangular shape, for example. The plurality of first limiting plates 22 and the plurality of second limiting plates 32 are perpendicularly provided so that short axes of the plurality of first limiting plates 22 and of the plurality of second limiting plates 32 are parallel to the Z axis direction. Thus, the plurality of first limiting plates 22 are provided so that their long axes are parallel to the Y axis direction. Further, the plurality of second limiting plates 32 are provided so that their long axes are parallel to the X axis direction.

Next, the following description will discuss, with reference to FIGS. 1 through 3, an effect of reducing a vapor deposition blur by use of the vapor deposition unit 1.

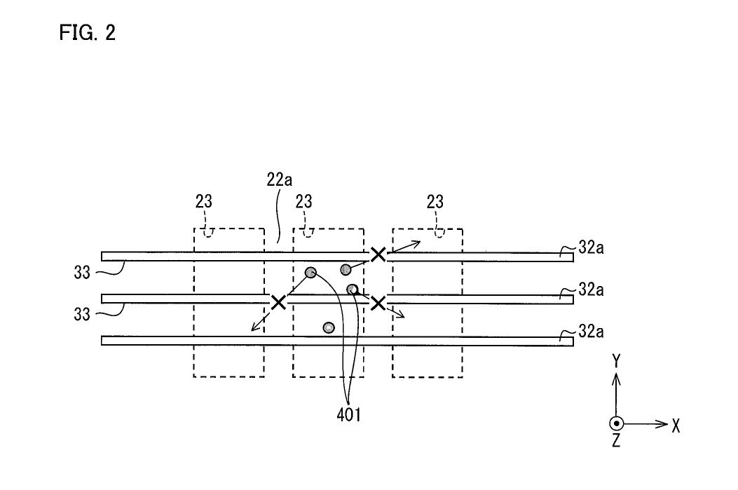

FIG. 2 is a substantial part plan view schematically illustrating, together with the vapor deposition particles 401 that have passed through the space between the respective plurality of first limiting plates 22 when the vapor deposition rate is high, the plurality of first limiting plates 22 and the plurality of second limiting plates 32 each viewed in the direction perpendicular to the principal surface of the vapor deposition mask 40.

As illustrated in FIGS. 1 and 2, according to Embodiment 1, in which the plurality of first limiting plates 22 and the plurality of second limiting plates 32 are provided so that an axis direction of the plurality of first limiting plates 22 and an axis direction of the plurality of second limiting plates 32 are perpendicular to each other, the plurality of second limiting plates 32 that are viewed in the direction perpendicular to the principal surface of the vapor deposition mask 40 are in non-parallel to the Y axis direction and extend in a direction intersecting with the Y axis direction. More strictly speaking, the plurality of second limiting plates 32 that are viewed in the direction perpendicular to the principal surface of the vapor deposition mask 40 have end surfaces 32a that intersect with each of (i) end surfaces 22a of the plurality of first limiting plates 22 of the first limiting plate row 21 that are viewed in the direction perpendicular to the principal surface of the vapor deposition mask 40 and (ii) limiting plate openings 33 provided between the plurality of first limiting plates 22. Note here that the end surfaces 22a of the plurality of first limiting plates 22 that are viewed in the direction perpendicular to the principal surface of the vapor deposition mask 40 refer to surfaces of the plurality of first limiting plates 22 which surfaces are different from the principal surfaces and are viewed in the direction perpendicular to the principal surface of the vapor deposition mask 40 (e.g., top surfaces or bottom surfaces of the plurality of first limiting plates 22 illustrated in FIG. 1). Similarly, the end surfaces 32a of the plurality of second limiting plates 32 that are viewed in the direction perpendicular to the principal surface of the vapor deposition mask 40 refer to surfaces of the plurality of second limiting plates 32 which surfaces are different from the principal surfaces and are viewed in the direction perpendicular to the principal surface of the vapor deposition mask 40 (e.g., top surfaces or bottom surfaces of the plurality of second limiting plates 32 illustrated in FIG. 1).

The vapor deposition particles 401 injected from the injection holes 11 of the vapor deposition source 10 isotropically spread in a form of vapor deposition flows. As illustrated in FIG. 1, the vapor deposition flows having such an isotropic distribution are controlled so as to have a distribution high in directivity by causing the plurality of first limiting plates 22 to block (capture) vapor deposition components included in the vapor deposition flows and having low directivity.

The vapor deposition flows thus controlled and high in vapor deposition speed have lower directivity after passing through the limiting plate opening 23 provided between the respective plurality of first limiting plates 22. This is because of collision and scattering of the vapor deposition particles 401 due to high kinetic energy of the vapor deposition flows.

As illustrated in FIG. 2, the vapor deposition flows having lower directivity are controlled so as to have a distribution high in directivity by causing the plurality of second limiting plates 32 to block again the vapor deposition components having low directivity.

The vapor deposition flows maintaining high directivity pass through the mask opening 41 of the vapor deposition mask 40 and are then vapor-deposited on the film formation target substrate 200.

In this case, Embodiment 1 makes it possible to form a selectively vapor-deposited layer of the vapor-deposited film 402 by scanning the film formation target substrate 200 in the Y axis direction.

As described above, Embodiment 1 is configured such that the axis direction of the plurality of first limiting plates 22 and the axis direction of the plurality of second limiting plates 32 are perpendicular to each other so that the end surfaces 32a of the plurality of second limiting plates 32 intersect with at least one of (i) the end surfaces 22a of the plurality of first limiting plates 22 of the first limiting plate row 21 and (ii) the limiting plate openings 33 provided between the plurality of first limiting plates 22. This allows the vapor deposition components having low directivity to be blocked by the plurality of second limiting plates 32 even in a case where the vapor deposition flows whose directivity has been improved by the plurality of first limiting plates 22 deteriorate (have a so-called isotropic distribution) after passing through the limiting plate opening 23.

Thus, the vapor deposition particles 401 that have passed through the second limiting plate unit 30 pass through the mask openings 41 of the vapor deposition mask 40 while maintaining high directivity, and are then vapor-deposited on the film formation target substrate 200. This allows a reduction in vapor deposition blur and makes it possible to form a high-definition vapor-deposited film pattern having an extremely small amount of vapor deposition blur.

Thus, a vapor deposition blur is greatly reduced in the case of, for example, the film formation target substrate 200 that is an organic EL substrate. This makes it unnecessary to, for example, cause a non-light emitting area between light emitting areas to have a larger width so that color mixture does not occur. Thus, it is possible to produce an organic EL display device capable of carrying out high-luminance and high-definition display. Further, since it is unnecessary to cause a luminescent layer to have a higher electric current density so as to, for example, increase a luminance of the organic EL display device, it is possible to achieve an organic EL display device having a long life and higher reliability.

Meanwhile, in a case where only the plurality of first limiting plates 22 are provided between the vapor deposition source 10 and the vapor deposition mask 40, it is necessary to reduce a gap between the respective plurality of first limiting plates 22 in the X axis direction or increase the length of the plurality of first limiting plates 22 so that a vapor deposition blur has a narrower width.

However, the reduction in gap between the respective plurality of first limiting plates 22 in the X axis direction causes a rapid decrease in aperture ratio of the plurality of first limiting plates 22. This reduces efficiency of utilization of the vapor deposition material. Meanwhile, in a case where the plurality of first limiting plates 22 have a longer length in the Z axis direction so that the plurality of first limiting plates 22 and the vapor deposition mask 40 come closer to each other, the plurality of first limiting plates 22 increase in weight and thermal expansion amount. This causes vapor deposition blurs to vary in width. Further, the plurality of first limiting plates 22 thus having a longer length in the Z axis direction cause collision and scattering of the vapor deposition particles to occur two or more times, so that the plurality of first limiting plates 22 also block vapor deposition components which are not supposed to cause a vapor deposition blur.

However, according to Embodiment 1, in which the vapor deposition unit 1 includes, in the Z axis direction, a plurality of limiting plate units provided so as to constitute respective of a plurality of stages, it is possible to efficiently block, in accordance with a distribution of vapor deposition flows, only a distribution of vapor deposition flows causing a vapor deposition blur. This reduces a material to be wasted on the limiting plates as in the limiting plates having a longer length in the Z axis direction (the direction normal to the film formation target substrate 200).

Assume that the plurality of limiting plate units are provided in the Z axis direction so as to constitute respective of the plurality of stages. In this case, it is possible to, for example, provide the plurality of first limiting plates 22 in the Z axis direction so as to constitute respective of the plurality of stages.

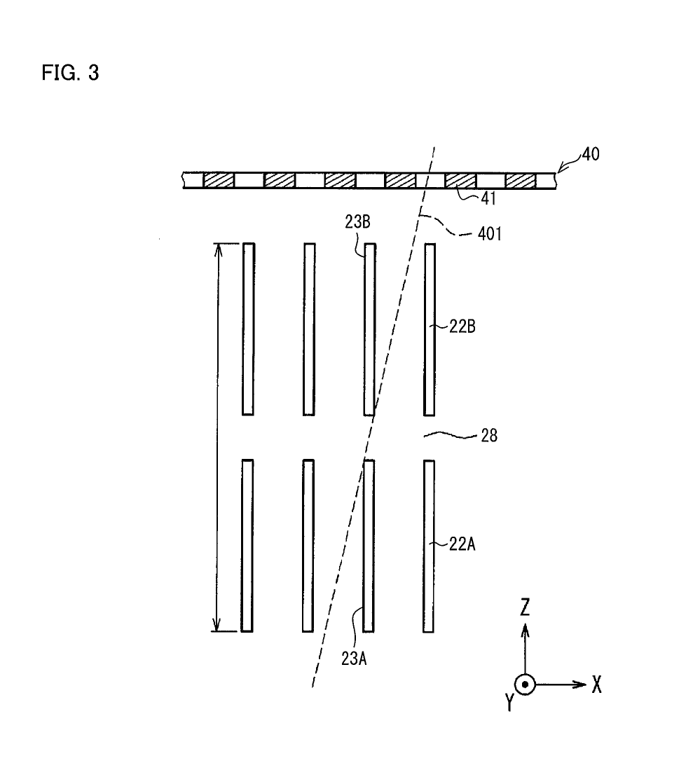

FIG. 3 is a cross-sectional view illustrating an example of a vapor deposition flow in a case where the first limiting plates 22 are provided via a gap 28 in the Z axis direction so as to constitute respective of two stages. Note that for convenience, the first limiting plates 22 provided at a lower stage of the two stages are herein referred to as first limiting plates 22A, and a limiting plate opening 23 provided between the respective first limiting plates 22A is herein referred to as a limiting plate opening 23A. Further, the first limiting plates 22 provided at an upper stage of the two stages are referred to as first limiting plates 22B, and a limiting plate opening 23 provided between the respective first limiting plates 22B is referred to as a limiting plate opening 23A.

However, in the case where the first limiting plates 22 are provided so as to constitute respective of the two stages as illustrated in FIG. 3, the vapor deposition particles 401 having obliquely exited through the limiting plate opening 23A provided between the respective first limiting plates 22A at the lower stage (i.e., on an upstream side), may (i) pass through the gap 28, (ii) pass through the limiting plate opening 23B that is different from that located directly above the limiting plate opening 23A, and then (iii) enter the mask opening 41.

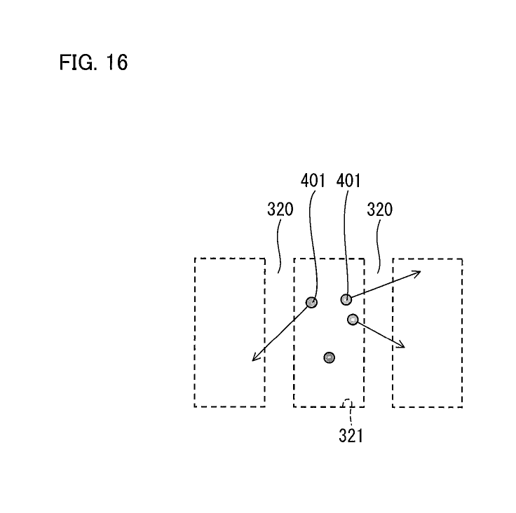

In this case, when viewed in the direction perpendicular to the principal surface of the vapor deposition mask 40, a state in which the vapor deposition particles 401 that have passed through the limiting plate opening 23A at the lower stage are scattered is identical to that illustrated in FIG. 16.

The first limiting plates 22 provided so as to constitute respective of the two stages as illustrated in FIG. 3 are highly likely to also block (i) vapor deposition components having high directivity and (ii) vapor deposition components which have low directivity and are changed, by repeated scattering and collision of particles, to vapor deposition components having high directivity. This may reduce a vapor deposition rate and/or material utilization efficiency.

However, as illustrated in FIG. 2, the vapor deposition particles 401 having low directivity can be efficiently blocked in a case where the second limiting plates 32 that are viewed in the direction perpendicular to the principal surface of the vapor deposition mask 40 are provided above (i.e., downstream of) the first limiting plates 22 so as to (i) be in non-parallel to the Y axis direction and (ii) intersect with the first limiting plates 22 or the limiting plate openings 23.

As described above, since a high vapor deposition rate causes the vapor deposition flows to spread in a wide range, a vapor deposition blur can be eliminated only by three-dimensionally limiting the spread of the vapor deposition flows. According to Embodiment 1, as described earlier, the vapor deposition unit 1 includes the second limiting plate unit which is located downstream of the first limiting plate unit 20 and differs from the first limiting plate unit 20 in axis direction. This makes it possible to three-dimensionally limit the spread of the vapor deposition flows. Thus, it is possible to control the vapor deposition flows having high kinetic energy as when the vapor deposition rate is high.

Thus, Embodiment 1 makes it possible to (i) reduce a vapor deposition blur occurring when the vapor deposition rate is high and (ii) further enhance material utilization efficiency as compared with a conventional technique. This allows a higher yield and higher productivity.

According to Embodiment 1, as described earlier, the vapor deposition unit 1 includes the plurality of limiting plate units provided in the Z axis direction so as to constitute respective of the plurality of stages, the plurality of limiting plate units each including a plurality of limiting plates. This allows the vapor deposition unit 1 to be easily suited to, for example, any substrate size, pattern size, and material.

Note that the first limiting plates 22 and the second limiting plates 32 are unheated or are cooled by a heat exchanger (not illustrated) so as to block obliquely scattering vapor deposition components. This causes the first limiting plates 22 and the second limiting plates 32 to have a lower temperature than the injection holes 11 of the vapor deposition source 10 (more strictly speaking, a temperature lower than a vapor deposition particle generation temperature at which a vapor deposition material turns into gas).

Thus, the first limiting plate unit 20 and the second limiting plate unit 30 can each appropriately include a cooling mechanism (not illustrated) for cooling the first limiting plates 22 and the second limiting plates 32. This causes the first limiting plates 22 and the second limiting plates 32 to cool and solidify the vapor deposition particles 401 which are unnecessary and incompletely parallel to the direction normal to the film formation target substrate 200. This allows the unnecessary vapor deposition particles 401 to be easily captured by the first limiting plates 22 and the second limiting plates 32, and consequently allows a direction in which the vapor deposition particles 401 travel to be closer to the direction normal to the film formation target substrate 200.

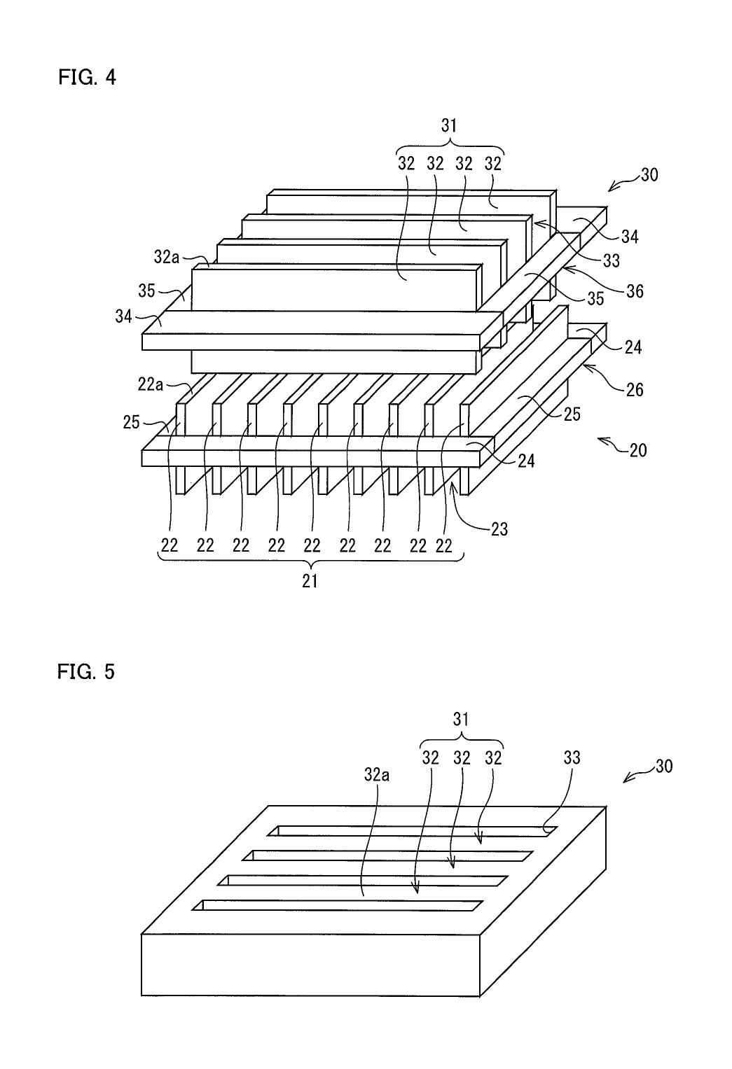

FIG. 4 is a perspective view schematically illustrating example configurations of the first limiting plate unit 20 and the second limiting plate unit 30.

The first limiting plates 22 are integrally held by a frame-like holding body 26 by, for example, a method such as welding. The frame-like holding body 26 is made up of (i) a pair of first holding members 24 that is parallel to the X axis direction and (ii) a pair of second holding members 25 that is parallel to the Y axis direction.

Similarly, the second limiting plates 32 are integrally held by a frame-like holding body 36 by, for example, the method such as welding. The frame-like holding body 36 is made up of (i) a pair of first holding members 34 that is parallel to the X axis direction and (ii) a pair of second holding members 35 that is parallel to the Y axis direction.

Note, however, that, a method for holding the limiting plates 22 and the second limiting plates 32 is not limited to the above method, provided that a relative position and postures of the first limiting plates 22 and the second limiting plates 32 can be kept constant.

FIG. 5 is a perspective view schematically illustrating another example configuration of the second limiting plate unit 30.

As illustrated in FIG. 5, the second limiting plate unit 30 can be a block-like unit which (i) includes a plurality of second limiting plates 32 provided so as to be spaced from each other and (ii) has limiting plate openings 33 between adjacent ones of the plurality of second limiting plates 32.

The second limiting plate unit 30 thus having a block shape as illustrated in FIG. 5 has advantages of, for example, (i) facilitating integration and alignment of a cooling mechanism with the second limiting plate unit 30 and (ii) facilitating replacement of the second limiting plate unit 30.

FIG. 5 shows, as an example, a case where the second limiting plate unit 30 has a block shape. Note, however, that it is needless to say that the first limiting plate unit 20 can also have a block shape as with the second limiting plate unit 30.

Note that FIG. 1 shows, as an example, a case where the vapor deposition source 10, the first limiting plate unit 20, the second limiting plate unit 30, and the vapor deposition mask 40 are provided so as to be spaced from each other by a certain gap in the Z axis direction.

Since the vapor deposition source 10, the first limiting plate unit 20, the second limiting plate unit 30, and the vapor deposition mask 40 are thus spaced from each other by a certain gap in the Z axis direction, it is possible to obtain a heat radiation effect and an effect of easily maintaining a space between adjacent ones of the limiting plate units at a predetermined degree of vacuum.

Note, however, that part or all of the vapor deposition source 10, the first limiting plate unit 20, the second limiting plate unit 30, and the vapor deposition mask 40 which part or all are adjacent to each other in the Z axis direction can be in contact (e.g., be integrated) with each other.

A case where the vapor deposition source 10, the first limiting plate unit 20, the second limiting plate unit 30, and the vapor deposition mask 40 are spaced from each other or are in contact with each other yields both advantageous and disadvantageous effects. This makes it only necessary to appropriately select and set an arrangement of the vapor deposition source 10, the first limiting plate unit 20, the second limiting plate unit 30, and the vapor deposition mask 40 so that a desired effect is obtained.

According to Embodiment 1, in which the first limiting plate unit 20 and the second limiting plate unit 30 are arranged as described earlier so as to be provided between the vapor deposition source 10 and the vapor deposition mask 40, it is possible to achieve the effects below.

This case, which makes it possible to capture, without fail, the vapor deposition particles 401 that have passed through a space between the respective first limiting plates 22 and have low directivity, has an advantage in that a vapor deposition blur is less likely to occur.

The case also has an advantage of extremely accurately aligning the first limiting plates 22 with the respective second limiting plates 32 by, for example, a pin alignment.

For example, the first limiting plates 22 provided with a cooling mechanism have an advantage in that the second limiting plates 32 can be cooled by the cooling mechanism provided for the first limiting plates 22 without the need to separately provide the second limiting plates with a cooling mechanism. Thus, it is possible to prevent reevaporation of the captured vapor deposition particles 401 with a simple configuration.

However, in this case, the vapor deposition particles 401 having low directivity are captured immediately after the vapor deposition particles 401 pass through the space between the respective first limiting plates 22. Some of the vapor deposition particles 401 having low directivity have higher directivity by repeating scattering before reaching the film formation target substrate 200. Thus, in this case, it is impossible to use such vapor deposition particles 401 that have higher directivity by repeating scattering before reaching the film formation target substrate 200.

(In a case where upper ends of first limiting plates 22 are not in close contact with lower ends of second limiting plates 32)

This case makes it possible to utilize an opportunity for the vapor deposition particles 401 having lower directivity after passing through the space between the respective first limiting plates 22 to have higher directivity. Thus, the case has an advantage of preventing a reduction in material utilization efficiency.

Contrary to this, for example, in a case where the vapor deposition particles 401 (i) have extremely high kinetic energy when the vapor deposition rate is high and (ii) massively decrease in directivity, the vapor deposition particles 401 having low directivity after passing through the space between the respective first limiting plates 22 may reach the film formation target substrate 200 after passing through a gap between the first limiting plates 22 and the second limiting plates 32 and consequently cause a vapor deposition blur.

This case makes it possible to extremely accurately align the second limiting plates 32 with the vapor deposition mask 40 by, for example, the pin alignment. Thus, the case has an advantage of making it easier to align the second limiting plates 32 with the vapor deposition mask 40 as compared with a case where the upper ends of the second limiting plates 32 are not in close contact with the vapor deposition mask 40.

Meanwhile, the case where the upper ends of the second limiting plates 32 are aligned with the vapor deposition mask 40 has a fear that the vapor deposition mask 40, which is typically thin, is damaged when the upper ends of the second limiting plates 32 are brought into close contact with the vapor deposition mask 40. Further, in a case where a thermal history of the second limiting plates 32 is transmitted to the vapor deposition mask 40, the vapor deposition mask 40 may deteriorate in accuracy depending on a temperature history of the second limiting plates 32.

This case has no fear that the vapor deposition mask 40 is damaged, so that the vapor deposition mask 40 does not deteriorate in accuracy.

Note that, unlike the first limiting plates 22, the second limiting plates 32 that have a longer length in the Z axis direction can capture more vapor deposition particles 401 having low directivity. This allows a greater effect of preventing the vapor deposition blur.

Meanwhile, the second limiting plates 32 that have an excessively long length in the Z axis direction account for a greater percentage of a vapor deposition chamber such as a vacuum chamber. Thus, more vapor deposition particles 401 are attached to the second limiting plates 32. This causes a fear of contamination and/or reevaporation and may cause a deterioration in light-emitting property of the organic EL display device.

The second limiting plates 32 which are in close contact with at least one of the first limiting plates 22 and the vapor deposition mask 40 form a space. This may cause the problem below. That is, depending on the length of the second limiting plates 32, it may be difficult to increase a degree of vacuum in the space, and may be rather easier to increase scattering of particles. Such a tendency is more clearly shown in the second limiting plates 32 that have a longer length in the Z axis direction. In particular, the second limiting plates 32 that are in close contact with both of the first limiting plates 22 and the vapor deposition mask 40 easily cause the above problem. Thus, in a case where the second limiting plates 32 having a long length in the Z axis direction are used, the second limiting plates 32, the first limiting plates 22, and the vapor deposition mask 40 are preferably provided so as to be spaced from each other by a certain gap.

The following description will discuss, with reference to FIG. 6, an example of the vapor deposition device 100 including the vapor deposition unit 1.

FIG. 6 is a cross-sectional view schematically illustrating a configuration of a substantial part of the vapor deposition device 100 in accordance with Embodiment 1. Note that FIG. 6 illustrates a cross section of the vapor deposition device 100 in accordance with Embodiment 1, the cross section extending so as to be parallel to the X axis direction.

As illustrated in FIG. 6, the vapor deposition device 100 in accordance with Embodiment 1 mainly includes a vacuum chamber 101 (a film-forming chamber), a substrate holder 102 (a substrate holding member), a substrate moving device 103, the vapor deposition unit 1, a vapor deposition unit moving device 104, an alignment observation section such as an image sensor 105, a shutter (not illustrated), and a control circuit (not illustrated) for controlling drive of the vapor deposition device 100.

The substrate holder 102, the substrate moving device 103, the vapor deposition unit 1, and the vapor deposition unit moving device 104 of the above members are provided in the vacuum chamber 101.

Note that in the vacuum chamber 101, a vacuum pump (not illustrated) is provided for vacuum-pumping the vacuum chamber 101 via an exhaust port (not illustrated) of the vacuum chamber 101 to keep a vacuum in the vacuum chamber 101 during vapor deposition.

The substrate holder 102 is a substrate holding member for holding the film formation target substrate 200. The substrate holder 102 holds the film formation target substrate 200, made of, for example, a TFT substrate, so that the vapor deposition target surface 201 faces the vapor deposition mask 40 of the vapor deposition unit 1.

The film formation target substrate 200 and the vapor deposition mask 40 are provided so as to face each other while being spaced from each other by a certain gap. Thus, the film formation target substrate 200 and the vapor deposition mask 40 have therebetween a gap having a certain height.

For the substrate holder 102, it is preferable to use, for example, an electrostatic chuck. The film formation target substrate 200 which is fixed to the substrate holder 102 by a method such as an electrostatic chuck is held by the substrate holder 102 without being bent by its own weight.

Embodiment 1 causes at least one of the substrate moving device 103 and the vapor deposition unit moving device 104 to carry out scan vapor deposition by moving the film formation target substrate 200 and the vapor deposition unit 1 with respect to each other so that the Y axis direction is the scanning direction.

The substrate moving device 103 includes, for example, a motor (not illustrated) and causes a motor drive control section (not illustrated) to drive the motor so as to move the film formation target substrate 200 held by the substrate holder 102.

The vapor deposition unit moving device 104, which includes, for example, a motor (not illustrated), causes a motor drive control section (not illustrated) to drive the motor so as to move the vapor deposition unit 1 with respect to the film formation target substrate 200.

By, for example, driving the motor (not illustrated), the substrate moving device 103 and the vapor deposition unit moving device 104 cause (i) alignment markers 42 provided in a non-opening area of the vapor deposition mask 40 and (ii) alignment markers 202 provided in a non-vapor deposition area of the film formation target substrate 200 to carry out positional correction so that positional displacement of the vapor deposition mask 40 and the film formation target substrate 200 is corrected.

The substrate moving device 103 and the vapor deposition unit moving device 104 can be, for example, a roller moving device or a hydraulic moving device.

The substrate moving device 103 and the vapor deposition unit moving device 104 can each include, for example, (i) a driving section made up of a motor (XYO driving motor) such as a stepping motor (pulse motor), a roller, a gear, and the like and (ii) a drive control section such as a motor drive control section, and can cause the drive control section to drive the driving section so that the film formation target substrate 200 or the vapor deposition unit 1 is moved. Further, the substrate moving device 103 and the vapor deposition unit moving device 104 can each include a driving section including, for example, an XYZ stage, and can be provided so as to be movable in any of the X axis direction, the Y axis direction, and the Z axis direction.

Note, however, that at least one of the film formation target substrate 200 and the vapor deposition unit 1 only needs to be provided so as to be movable with respect to the other. In other words, at least one of the substrate moving device 103 and the vapor deposition unit moving device 104 only needs to be provided.

For example, in a case where the film formation target substrate 200 is movably provided, the vapor deposition unit 1 can be fixed to an inner wall of the vacuum chamber 101. Meanwhile, in a case where the vapor deposition unit 1 is movably provided, the substrate holder 102 can be fixed to the inner wall of the vacuum chamber 101.

The vapor deposition unit 1 includes, for example, the vapor deposition source 10, the first limiting plate unit 20, the second limiting plate unit 30, the vapor deposition mask 40, the holder 50, a deposition preventing plate 60, and a shutter (not illustrated). Note that a description of the vapor deposition source 10, the first limiting plate unit 20, the second limiting plate unit 30, and the vapor deposition mask 40, which have already been described, is omitted here.

The holder 50 is a holding member for holding the vapor deposition source 10, the first limiting plate unit 20, the second limiting plate unit 30, and the vapor deposition mask 40.

The holder 50 includes, for example, a pair of sliding devices 51 and supporting members 52. The pair of sliding devices 51 and the supporting members 52 hold both the first limiting plate unit 20 and the second limiting plate unit 30.

The sliding devices 51 are provided so as to face each other at both ends of the holder 50 in the X axis direction. The supporting members 52 are provided on respective sides of the sliding devices 51 on which sides the sliding devices 51 face each other. The supporting members 52 can be slidably displaced in the Z axis direction and the X axis direction while facing each other. Movement of the supporting members 52 is controlled by the sliding devices 51 and/or by collaboration between (a) the sliding devices 51 (b) a limiting plate control device (not illustrated).

The first limiting plate unit 20 includes, for example, the frame-like holding body 26 as described earlier. The second limiting plate unit 30 includes, for example, the frame-like holding body 36 as described earlier.

The frame-like holding body 26 has both ends in the X axis direction which are provided with supporting sections 27 detachably provided on the respective supporting members 52. The frame-like holding body 36 has both ends in the X axis direction which are provided with supporting sections 37 detachably provided on the respective supporting members 52. This allows the first limiting plate unit 20 and the second limiting plate unit 30 to be detachable from the holder 50, so that vapor deposition materials accumulated on the first limiting plate unit 20 and the second limiting plate unit 30 can be regularly collected.

Note that the vapor deposition materials, which are melted or evaporated by being heated, can be easily collected by being heat-treated. The vapor deposition mask 40, which is required to be high in accuracy of dimension such as an opening width and flatness, may be distorted by heat treatment and thus cannot be heat-treated. However, the first limiting plate unit 20 and the second limiting plate unit 30, which are not required to be as high in accuracy of dimension as the vapor deposition mask 40, can be heat-treated, so that the accumulated vapor deposition materials can be easily collected. This allows high material utilization efficiency.

The vapor deposition unit 1 desirably includes, for example, the holder 50 that is provided with a tension mechanism 53 for applying tension to the vapor deposition mask 40. This makes it possible to horizontally hold the vapor deposition mask 40 while applying tension to the vapor deposition mask 40, so that a relative positional relationship between (a) the vapor deposition mask 40 and (b) the vapor deposition source 10, the first limiting plate unit 20, and the second limiting plate unit 30 can be fixed.

The vapor deposition device 100 can be configured such that (i) the vapor deposition particles 401 scattered from the vapor deposition source 10 are adjusted to scatter into the vapor deposition mask 40 and (ii) the vapor deposition particles scattered out of the vapor deposition mask 40 are appropriately blocked by, for example, the deposition preventing plate 60 (shielding plate).

In order to prevent the vapor deposition particles from flying toward the film formation target substrate 200, it is desirable to cause a shutter (not illustrated) to control the vapor deposition particles 401 to reach or not to reach the vapor deposition mask 40.

Thus, in order to control the vapor deposition particles 401 to reach or not to reach the vapor deposition mask 40, it is possible to appropriately provide, for example, between the vapor deposition source 10 and the first limiting plate unit 20, a shutter (not illustrated) such that the shutter can be moved back and forth (can be inserted and drawn out) based on a vapor deposition OFF signal or a vapor deposition ON signal.

In a case where the shutter is appropriately provided between the vapor deposition source 10 and the first limiting plate unit 20, it is possible to prevent vapor deposition on the non-vapor deposition area which is not subjected to vapor deposition. Note that the shutter may be provided integrally with the vapor deposition source 10 or may be provided separately from the vapor deposition source 10.

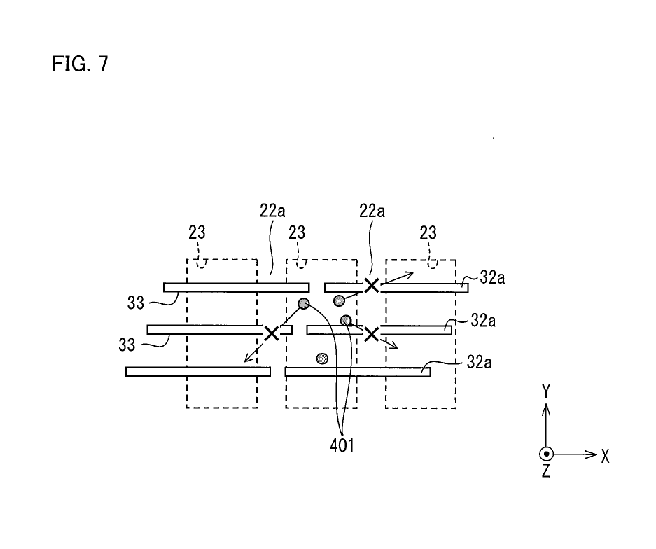

FIG. 7 is a substantial part plan view schematically illustrating another configuration of the limiting plate unit in accordance with Embodiment 1. FIG. 7 schematically illustrates, together with the vapor deposition particles 401 that have passed through the space between the respective first limiting plates 22 when the vapor deposition rate is high, the first limiting plates 22 and the second limiting plates 32 each viewed in the direction perpendicular to the principal surface of the vapor deposition mask 40.

As described above, the vapor deposition flows which have been isotropically spread after passing through the space between the respective first limiting plates 22 are blocked by the second limiting plates 32. Then, the vapor deposition flows pass through the mask opening 41 of the vapor deposition mask 40 while having directivity and are then vapor-deposited on the film formation target substrate 200, so that the vapor deposition blur can be reduced.

FIGS. 1 and 6 each show, as an example, a case where the second limiting plates 32 are continuously provided in the X axis direction. Alternatively, the second limiting plates 32 can be intermittently provided in the X axis direction. That is, the second limiting plates 32 can be discontinuous. In this case, discontinuous parts of the second limiting plates 32 neither need to be aligned at a specific position in the X axis nor need to have an equal length. Positions of the discontinuous parts only need to be appropriately determined in accordance with, for example, (i) an arrangement of the injection holes 11 (nozzle distribution) of the vapor deposition source 10 to be used and/or (ii) vapor deposition distribution.

The second limiting plates 32 which are continuously provided in the X axis direction have an advantage of being easily provided. Meanwhile, in a case where the second limiting plates 32 are intermittently provided in the X axis direction as described above, it is possible to constitute each of the second limiting plates 32 by combining small parts. This provides an advantage of allowing (i) maintenance such as replacement of the limiting plates and (ii) precise adjustment in accordance with the nozzle distribution and the vapor deposition distribution.

FIG. 1 shows, as an example, a case where, while the vapor deposition source 10 is provided below the film formation target substrate 200 and the vapor deposition target surface 201 of the film formation target substrate 200 faces downward, vapor deposition is carried out on the film formation target substrate 200 by injecting the vapor deposition particles 401 upward from the vapor deposition source 10 so as to vapor-deposit the vapor deposition particles 401 onto the film formation target substrate 200 (up-deposition).

However, the vapor deposition method is not limited to this. It is possible to provide the vapor deposition source 10 above the film formation target substrate 200 and carry out vapor deposition on the film formation target substrate 200 by injecting the vapor deposition particles 401 downward from the vapor deposition source 10 so as to vapor-deposit the vapor deposition particles 401 onto the film formation target substrate 200 (down-deposition).

Thus, in this case, the vapor deposition source 10, the first limiting plate unit 20, the second limiting plate unit 30, the vapor deposition mask 40, and the film formation target substrate 200 are arranged in an order opposite to that in which these members are arranged in each of the examples shown in FIGS. 1 and 6.

Alternatively, for example, the vapor deposition source 10 can have a mechanism for injecting the vapor deposition particles 401 in a lateral direction. In such a case, the vapor deposition particles 401 injected in the lateral direction are vapor-deposited on the film formation target substrate 200 (side-deposition) while the vapor deposition target surface 201 of the film formation target substrate 200 lies in the vertical direction so that the vapor deposition target surface 201 faces the vapor deposition source 10. In this case, an arrangement of the vapor deposition source 10, the first limiting plate unit 20, the second limiting plate unit 30, the vapor deposition mask 40, and the film formation target substrate 200 is obtained by rotating, by 90 degrees in a right or left direction, the example arrangement shown in each of FIGS. 1 and 6.

The above description of Embodiment 1 has taken, as an example, a case where the first limiting plates 22 and the second limiting plates 32 are provided so as to be perpendicular to the principal surface of the vapor deposition mask 40. Note, however, that the principal surfaces of each of the first limiting plates 22 and the principal surfaces of each of the second limiting plates 32 can be provided so as to incline in the Z axis direction.

However, the first limiting plates 22 and the second limiting plates 32, each of which can be easily arranged and is not likely to block the vapor deposition particles having high directivity, are preferably provided so as to be perpendicular to the principal surface of the vapor deposition mask 40.

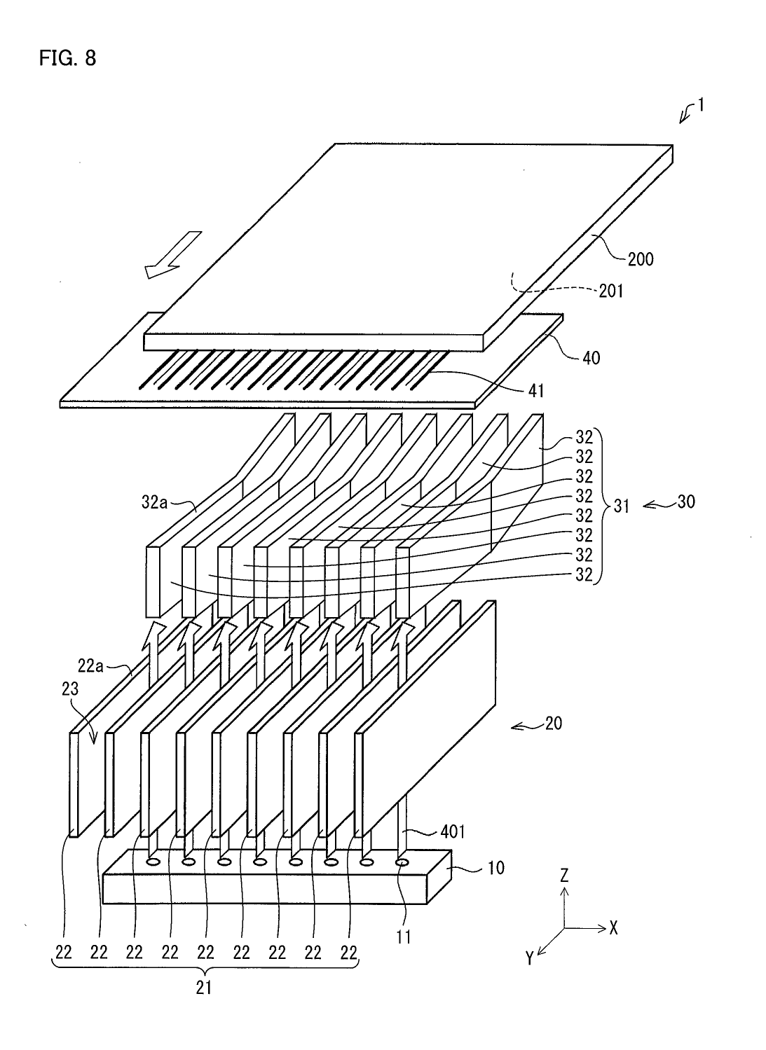

Embodiment 2 is described below with reference to FIG. 8 and FIGS. 11A-11C.

Embodiment 2 mainly describes differences from Embodiment 1. Note that members that have identical functions to those of Embodiment 1 are given identical reference numerals, and are not explained repeatedly.

In a case where directivity of vapor deposition particles 401 slightly decreases by collision and scattering of vapor deposition particles 401, a vapor deposition blur can be sufficiently reduced by providing the second limiting plate unit 30 described in Embodiment 1.

However, in a case where the vapor deposition particles 401 massively decrease in directivity, it is difficult to say that the second limiting plate unit 30 described in Embodiment 1 is sufficient to reduce the vapor deposition blur.

This is because the vapor deposition particles 401 which have lower directivity are more likely to fly closer to the X axis and the second limiting plate unit 30 described in Embodiment 1 cannot block the vapor deposition particles 401 flying closer to the X axis.

Thus, in a case where the vapor deposition particles 401 massively decrease in directivity, the vapor deposition particles 401 having low directivity are desirably captured by second limiting plates 32 which are provided so as to be closer to the X axis.

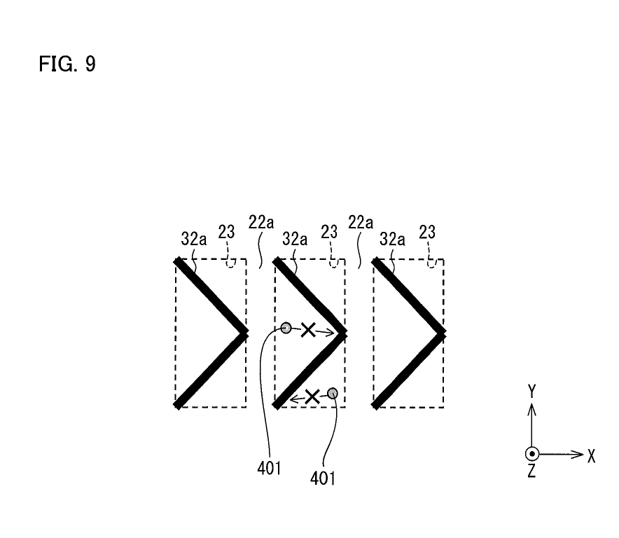

FIG. 8 is a perspective view schematically illustrating, together with a film formation target substrate 200, a configuration of a substantial part of a vapor deposition unit 1 of a vapor deposition device 100 in accordance with Embodiment 2. FIG. 9 is a substantial part plan view schematically illustrating, together with the vapor deposition particles 401 that have passed through a space between respective first limiting plates 22 when a vapor deposition rate is high, the first limiting plates 22 and second limiting plates 32 each viewed in a direction perpendicular to a principal surface of a vapor deposition mask 40.

As illustrated in FIGS. 8 and 9, the vapor deposition unit 1 in accordance with Embodiment 2 is identical in configuration to the vapor deposition unit 1 in accordance with Embodiment 1 except (i) that, when viewed in the direction perpendicular to the main surface of the vapor deposition mask 40, the second limiting plates 32, more strictly speaking, end surfaces 32a of the second limiting plates 32 have a bent shape and are provided in parallel to each other in an X axis direction at equal pitches and (ii) that a limiting plate opening 33 having a bent shape is provided between the respective second limiting plates 32, which are adjacent to each other in the X axis direction.

As in Embodiment 1, the vapor deposition unit 1 in accordance with Embodiment 2 includes the first limiting plates 22 and the second limiting plates 32. The first limiting plates 22 and the second limiting plates 32 are provided so as not to be parallel to each other in a single YZ plane. When viewed in the direction perpendicular to the principal surface of the vapor deposition mask 40, the second limiting plates 32 are in non-parallel to a Y axis direction and extend in a direction intersecting with the Y axis direction.

Thus, Embodiment 2 also allows the second limiting plate unit 30 to block the vapor deposition flows which have been isotropically spread after passing through the first limiting plate unit 20. Thus, since the vapor deposition particles 401 that have passed through a mask opening 41 of the vapor deposition mask 40 while having directivity are vapor-deposited on the film formation target substrate 200, the vapor deposition blur can be reduced.

However, according to Embodiment 2, the second limiting plates 32, which are bent, are continuously provided in the Y axis direction so as to be closer to the X axis direction.

This makes it possible to also block the vapor deposition particles 401 that are closer to the X axis direction. Thus, it is possible to limit scattering of vapor deposition flows having high kinetic energy when the vapor deposition rate is higher. Such vapor deposition flows cannot be blocked by merely causing an axis direction of the first limiting plates 22 and an axis direction of the second limiting plates 32 to be perpendicular to each other. This makes it possible to reduce the vapor deposition blur even in a case where the vapor deposition particles 401 massively decrease in directivity due to collision and scattering of the vapor deposition particles 401.

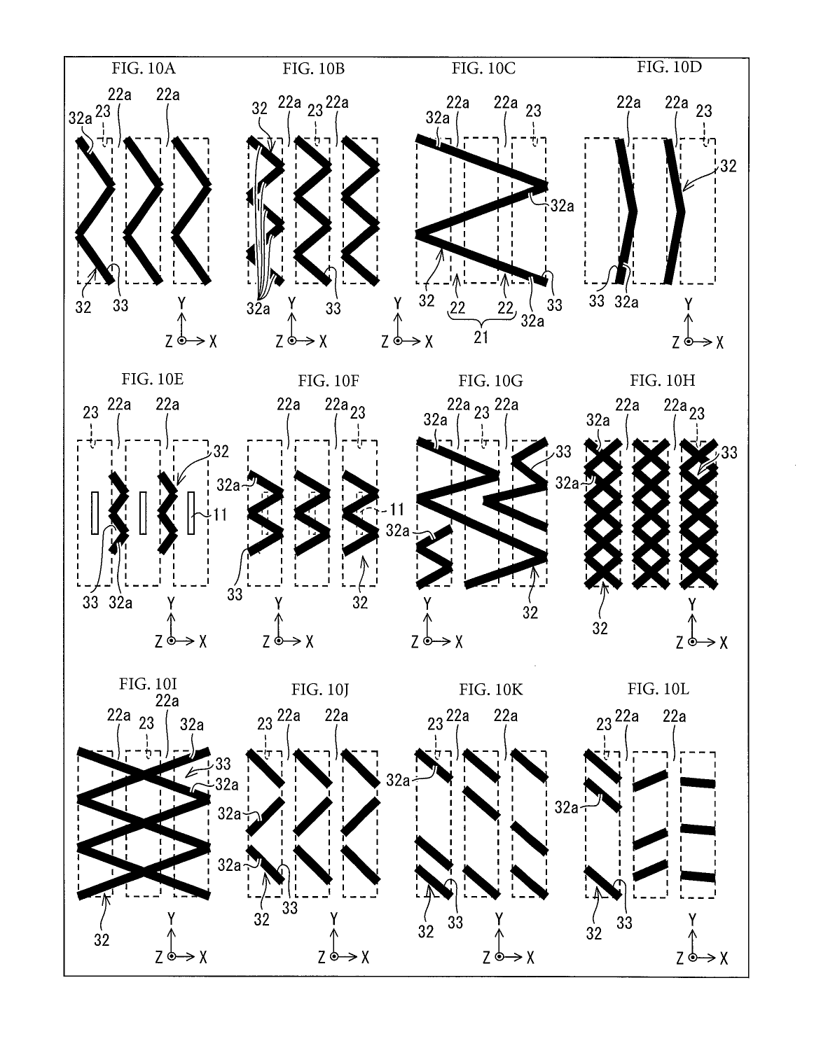

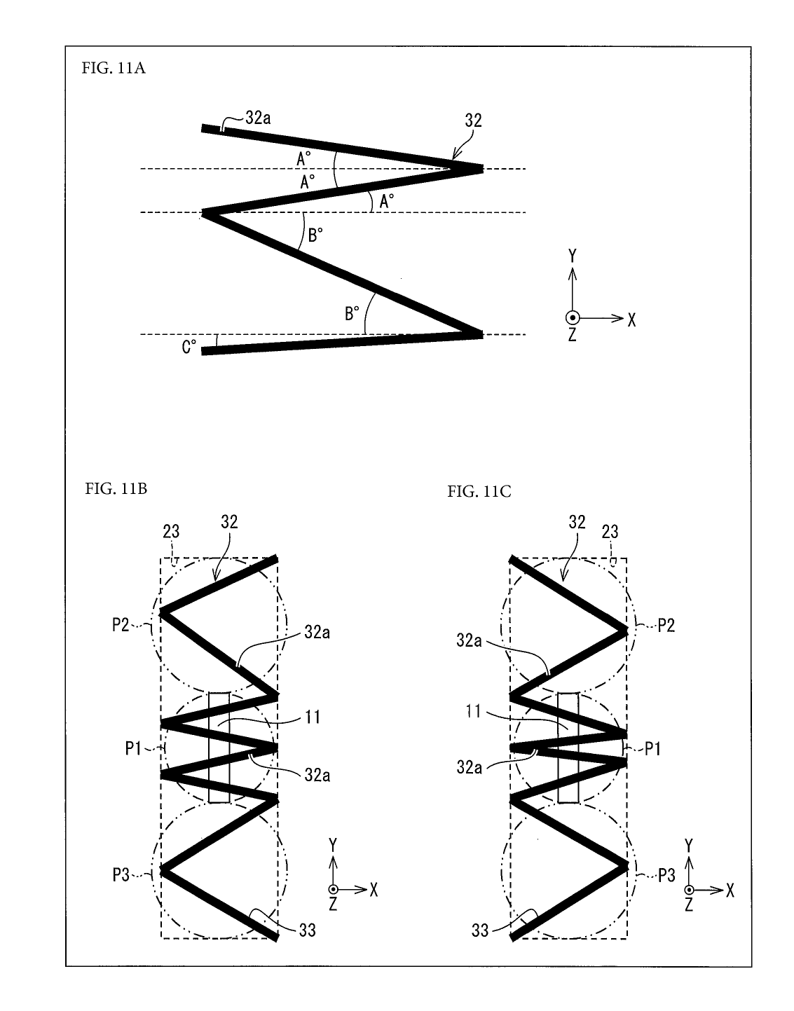

FIGS. 10A-10L are substantial part plan views each schematically illustrating another configuration of the limiting plate units in accordance with Embodiment 2. FIGS. 10A-10L each schematically illustrate the first limiting plates 22 and the second limiting plates 32 each viewed in the direction perpendicular to the principal surface of the vapor deposition mask 40.

FIGS. 8 and 9 each show, as an example of the second limiting plates 32 having a bent shape, a case where the second limiting plates 32 have a > shape (i.e., a V shape opening in a direction perpendicular to a scanning direction) when viewed in the direction perpendicular to the principal surface of the vapor deposition mask 40.

However, the number of bend points does not need to be one as illustrated in FIGS. 8 and 9, but may be two or more as illustrated in FIGS. 10A and 10B. Thus, the second limiting plates 32 can have a zigzag shape. Alternatively, two or more second limiting plates 32 can be zigzag-provided.

A larger number of bend points cause the second limiting plates 32 to block more vapor deposition components (vapor deposition particles 401) having low directivity, so that the vapor deposition blur is further reduced.

FIG. 9 and FIGS. 10A and 10B each show, an example, a case where the second limiting plates 32 are provided only above respective limiting plate openings 23 provided between the first limiting plates 22. Note, however, that, as in the case of the second limiting plates 32 in accordance with Embodiment 1, the second limiting plates 32 can be continuously provided in the X axis direction so as to extend across two or more first limiting plates 22 (see, for example, FIG. 10C). In this case, for example, the second limiting plates 32 can be provided throughout a first limiting plate row 21 so as to (i) have bend points only at ends of the first limiting plate row 21 and (ii) extend across two or more first limiting plates 22.

As illustrated in FIGS. 10D and 10E, the second limiting plates 32 can be provided only directly above the respective first limiting plates 22 when viewed in the direction perpendicular to the principal surface of the vapor deposition mask 40. In this case, for example, as illustrated in FIG. 10D, the second limiting plates 32 can each be provided so as to, for example, extend from one end to the other end of a corresponding first limiting plate when viewed in the direction perpendicular to the principal surface of the vapor deposition mask 40. Alternatively, the second limiting plates 32 can be partially provided when viewed in the direction perpendicular to the principal surface of the vapor deposition mask 40. For example, the second limiting plates 32 can be provided only in a given region of the first limiting plates 22.

For example, the vapor deposition particles 401 are highly likely to collide with each other in a region near and above injection holes 11, in which region vapor deposition density is high. This easily causes a deterioration in directivity of the vapor deposition particles 401. Meanwhile, since the vapor deposition density decreases in a region more distant from the injection holes 11, the vapor deposition particles 401 are less likely to deteriorate in directivity.

Thus, as illustrated in FIG. 10E, the second limiting plates 32 can be provided, for example, only in a region directly above the respective first limiting plates 22 and near and above the injection holes 11 (e.g., (i) a region in which a belt-shaped row of the injection holes 11 provided in the X axis direction intersects (overlaps) with the first limiting plates 22 when viewed in the direction perpendicular to the principal surface of the vapor deposition mask 40 or (ii) the region and a region near the region). Note that the injection holes 11 are provided above respective central parts of the limiting plate openings 23 provided between the first limiting plates 22. Thus, in this case, the second limiting plates 32 can be provided, for example, only in a region in which central parts of the first limiting plates 22 are located (see FIG. 10E).

Note that it is needless to say that the second limiting plates 32 can be provided only in a region above the respective limiting plate openings 23 provided between the first limiting plates 22 and near and above the injection holes 11 (see FIG. 10F). It is still more needless to say that the second limiting plates 32 can be provided only in both parts illustrated in FIG. 10E and parts illustrated in FIG. 10F. That is, the second limiting plates 32 can be provided only in a region near and above the injection holes 11 as illustrated in FIG. 10E and FIG. 10F.

Further, a region above the first limiting plates 32 can be (i) a region in which the second limiting plates 32 are concentratedly provided and (ii) a region in which no second limiting plate 32 is provided or the second limiting plates 32 are provided at long intervals, i.e., the second limiting plates 32 can be provided at either short or long intervals (see, for example, FIGS. 10E and 10G).

As described above, the second limiting plate unit 30 only needs to be configured such that, when viewed in the direction perpendicular to the principal surface of the vapor deposition mask 40, end surfaces 32a of the second limiting plates 32 intersect with at least one of (i) end surfaces 22a of the first limiting plates 22 of the first limiting plate row 21 and (ii) the limiting plate openings 23 provided between the first limiting plates 22. That is, when viewed in the direction perpendicular to the principal surface of the vapor deposition mask 40, the second limiting plates 32 (the end surfaces 32a of the second limiting plates 32) only need to extend in a direction intersecting with the Y axis direction the direction being (i) a direction in which the end surfaces 22a of the first limiting plates 22 extend and (ii) a direction (an opening length direction) in which the limiting plate openings 23 provided between the first limiting plates 22 extend.

A more desirable pattern of such patterns of the second limiting plates 32 as described above is a pattern in which, when viewed in the direction perpendicular to the principal surface of the vapor deposition mask 40, the end surfaces 32a of the second limiting plates 32 intersect with at least the limiting plate openings 23 provided between the first limiting plates 22. That is, the more desirable pattern is a pattern in which the limiting plate openings 23 provided between the first limiting plates 22 are each partitioned in a direction different from the X axis direction when viewed in the direction perpendicular to the principal surface of the vapor deposition mask 40.

FIG. 9 and FIGS. 10A-10F each show, as an example, a case where bend lines of the second limiting plates 32 are symmetric with respect to the X axis. Note, however, that Embodiment 2 is not limited to this. For example, as illustrated in FIG. 10G, the bend lines can vary in length. Further, the bend lines can vary in angle (bend angle) as described later.

FIGS. 11A-11C are plan views each showing an example of another pattern of a second limiting plate 32.

FIG. 11A shows, as the example of the another pattern of the second limiting plate 32, a case where the second limiting plate 32 has a different bend angle at each bend point. FIGS. 11B and 11C each show a relationship between (i) bend angles of the second limiting plate 32 of the another pattern and (ii) directivity of the vapor deposition particles 401.

Note that a relationship among the bend angles of the second limiting plate 32, which are indicated by A°, B°, and C° in FIG. 11A, is B°>A°>C° as illustrated in FIG. 11A.

The second limiting plate 32 can have a shape illustrated in FIG. 11A. Alternatively, the second limiting plate 32 can include a plurality of second limiting plates that are provided so as to have a shape illustrated in FIG. 11A.

The bend angles of the second limiting plate 32 only need to be determined in accordance with (i) an arrangement of the injection holes 11 (nozzle distribution) in the vapor deposition source 10 and (ii) vapor deposition distribution.

As described earlier, the vapor deposition particles 401 which have lower directivity fly closer to the X axis. On the contrary, the vapor deposition particles 401 which have high directivity fly closer to the Y axis. Thus, in a case where the vapor deposition particles 401 massively decrease in directivity, the vapor deposition particles 401 having low directivity are desirably captured by the second limiting plate 32 whose bend lines are closer to the X axis. Meanwhile, as the vapor deposition particles 401 have higher directivity, the second limiting plate 32 can have a greater angle with respect to the X axis (i.e., have an angle closer to 90 degrees with respect to the X axis).

Thus, the second limiting plate 32 only needs to have, for example, (i) a bend angle that is relatively large in a region in which the vapor deposition particles 401 are less likely to deteriorate in directivity and (ii) a bend angle that is relatively small in a region in which the vapor deposition particles 401 deteriorate in directivity.

As described earlier, the vapor deposition particles 401 easily deteriorate in the region near and above the injection holes 11, and the vapor deposition particles 401 are less likely to deteriorate in directivity in the region more distant from the injection holes 11. Thus, as illustrated in FIGS. 11B and 11C, the second limiting plate 32 when viewed in the direction perpendicular to the principal surface of the vapor deposition mask 40 can have (i) a bend angle that is relatively small in a region P1 (e.g., a region above a central part of a limiting plate opening 23) which is relatively close to an injection hole 11 and is shown in a dash-dot line in each of FIGS. 11B and 11C and (ii) a bend angle that is relatively great in each of regions P2 and P3 (e.g., regions above the limiting plate opening 23 and closer to both ends of the limiting plate opening 23 in the Y axis direction) which are relatively distant from the injection hole 11 and are shown in a dash-dot-dot line in each of FIGS. 11B and 11C. Further, as illustrated in FIG. 11C, the second limiting plate 32 that is viewed in the direction perpendicular to the principal surface of the vapor deposition mask 40 can be designed or provided to have a greater bend angle in the region which is more distant from the injection hole 11 (i.e., more distant in the Y axis direction from the injection hole 11 or a center of the injection hole 11).

Note that the second limiting plates 32 can be integrally provided in the regions P1 through P3 or can be separately provided in the respective regions P1 through P3. In a case where the second limiting plates 32 are separately provided in the respective regions P1 through P3, the second limiting plates 32 can have a bent shape. Alternatively, two or more second limiting plates 32 having a flat shape can be combined so as to be zigzag-provided when viewed in the direction perpendicular to the principal surface of the vapor deposition mask 40. This means that the above description can reword (i) the “bend angle” as an “arrangement density”, (ii) “the bend angle is (relatively) large” as “the arrangement density is (relatively) low”, and (iii) “the bend angle is (relatively) small” as “the arrangement density is (relatively) high”.

That is, according to the configuration illustrated in FIG. 11B, the second limiting plates 32 that are viewed in the direction perpendicular to the principal surface of the vapor deposition mask 40 can be considered to have (i) an arrangement density that is relatively high in the region P1 which is relatively close to the injection hole 11 and (ii) an arrangement density that is relatively low in the regions P2 and P3 each of which is relatively distant from the injection hole 11. Meanwhile, according to the configuration illustrated in FIG. 11C, the second limiting plates 32 that are viewed in the direction perpendicular to the principal surface of the vapor deposition mask 40 can be considered to have an arrangement density that is lower in the region more distant from the injection hole 11.

Such a configuration makes it possible to (i) prevent or reduce blocking of the vapor deposition particles 401 having high directivity and (ii) efficiently block the vapor deposition particles 401 having low directivity and flying closer to the X axis direction.

FIG. 11B shows, as an example, a case where the second limiting plate 32 has the bend points in the limiting plate opening 23 between the first limiting plates 22. Note, however, that it is needless say that the bend points can be located outside the limiting plate opening 23, e.g., on an end surface 22a of a first limiting plate 22. Further, it is needless to say that the second limiting plate 32 can be provided so as to extend across two or more first limiting plates 22 regardless of whether or not the bend points are located in the limiting plate opening 23.

As described above, when viewed in the direction perpendicular to the principal surface of the vapor deposition mask 40, the end surface 32a of the second limiting plate 32 can have a bend angle that varies depending on positions of the bend points.

Further, as illustrated FIGS. 10H and 10I, the second limiting plates 32 can be provided so as to intersect with each other. Note that, also in this case, the second limiting plate unit 30 only needs to be configured such that, when viewed in the direction perpendicular to the principal surface of the vapor deposition mask 40, the end surfaces 32a of the second limiting plates 32 intersect with at least one of (i) the end surfaces 22a of the first limiting plates 22 of the first limiting plate row 21 and (ii) the limiting plate openings 23 provided between the first limiting plates 22 (see FIGS. 10H and 10I).

The second limiting plates 32, which are provided so as to have intersections as illustrated in FIGS. 10H and 10I, block more vapor deposition components having low directivity, so that the vapor deposition blur is further reduced.

Further, as illustrated in FIG. 10J, the second limiting plates 32 can be provided so as to be spaced from each other in the Y axis direction and be in non-parallel to each other. Thus, the second limiting plates 32 do not need to be continuously provided. Also in this case, the second limiting plates 32 which are provided so as to be closer to the X axis when viewed in the direction perpendicular to the principal surface of the vapor deposition mask 40 can efficiently capture the vapor deposition particles 401 that have passed through the first limiting plate unit 20 and have low directivity.

In this case, the second limiting plates 32 can be made of a combination of small parts. This makes it possible to carry out (i) maintenance such as replacement of the limiting plates and (ii) precise adjustment in accordance with the nozzle distribution and the vapor deposition distribution.

Further, the second limiting plates 32 can each curve or wave. This makes it possible to broaden material selectivity for forming the second limiting plates 32.

As illustrated in FIGS. 10K and 10L, the second limiting plates 32 which are provided so as to be closer to the X axis can be spaced from each other in the Y axis direction and be parallel to each other. In this case, not all of the second limiting plates 32 need to be provided in parallel to each other as illustrated in FIG. 10K. For example, as illustrated in FIG. 10L, second limiting plates 32 of a second limiting plate row 31 (i.e., a single second limiting plate row 31) can be provided in parallel to each other, but second limiting plate rows 31 that are adjacent to each other in the X axis direction can differ in direction in which the second limiting plates 32 are provided. That is, a first second limiting plate row 31 and a second second limiting plate row 31 adjacent to the first second limiting plate row 31 do not need to be identical in direction in which the second limiting plates 32 are provided. Further, as illustrated in FIGS. 10K and 10L, second limiting plates 32 of one second limiting plate row 31 can be provided at equal pitches or at partially different pitches. It is needless say that the effects described earlier can be obtained in any case.

Assume that the pitches at which the second limiting plates 32 are provided are changed as described above. In this case, in order that the second limiting plates 32 that are viewed in the direction perpendicular to the principal surface of the vapor deposition mask 40 have, as described earlier, (i) an arrangement density that is relatively high in a region which is relatively close to the injection hole 11 and (ii) an arrangement density that is relatively low in a region which is relatively distant from the injection hole 11, the second limiting plates 32 can be designed to be provided at relatively small pitches in the region which is relatively close to the injection hole 11 and at relatively large pitches in the region that is relatively distant from the injection hole 11.

In a case where the arrangement density of the second limiting plates 32 is set as described earlier in Embodiments 1 and 2, it is possible to (i) to prevent or reduce blocking of the vapor deposition particles 401 having high directivity and (ii) efficiently block the vapor deposition particles 401 having low directivity.

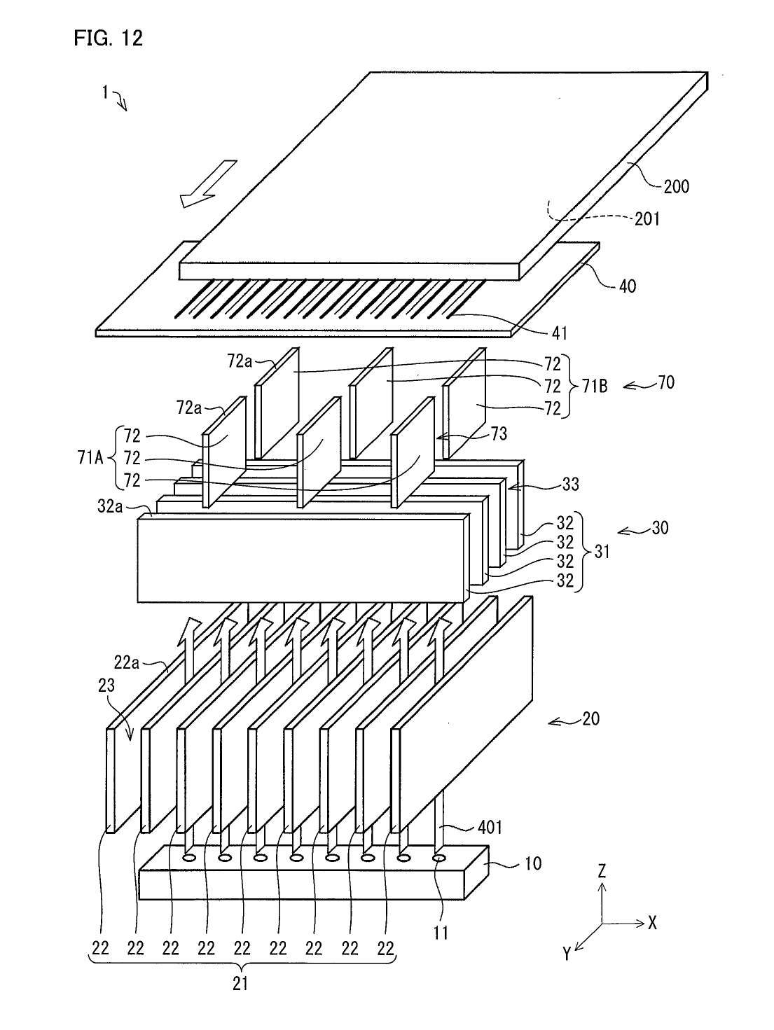

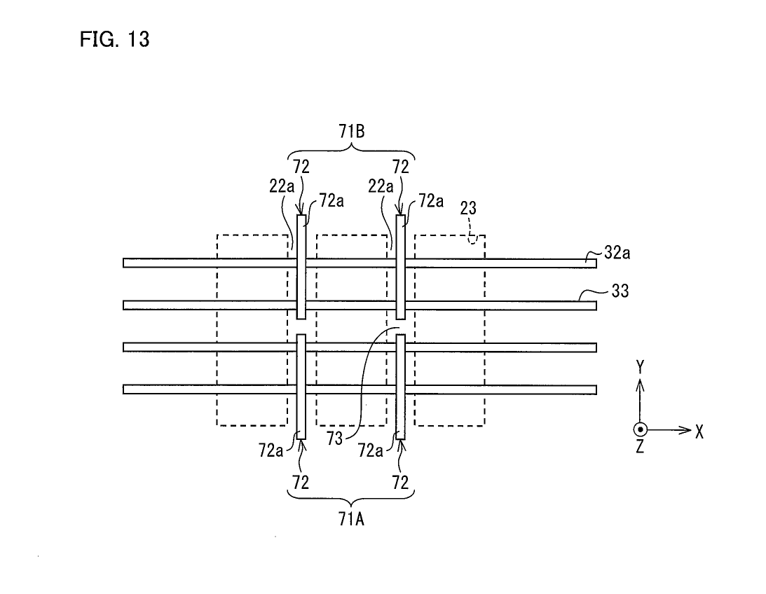

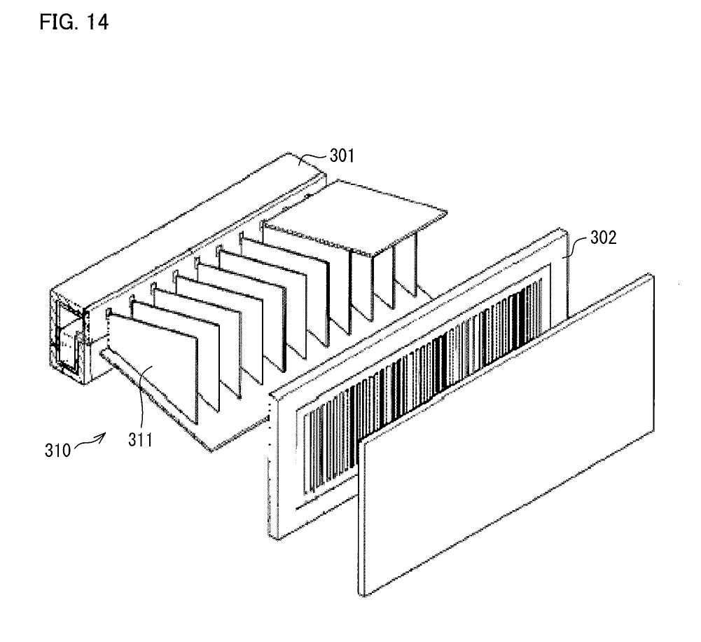

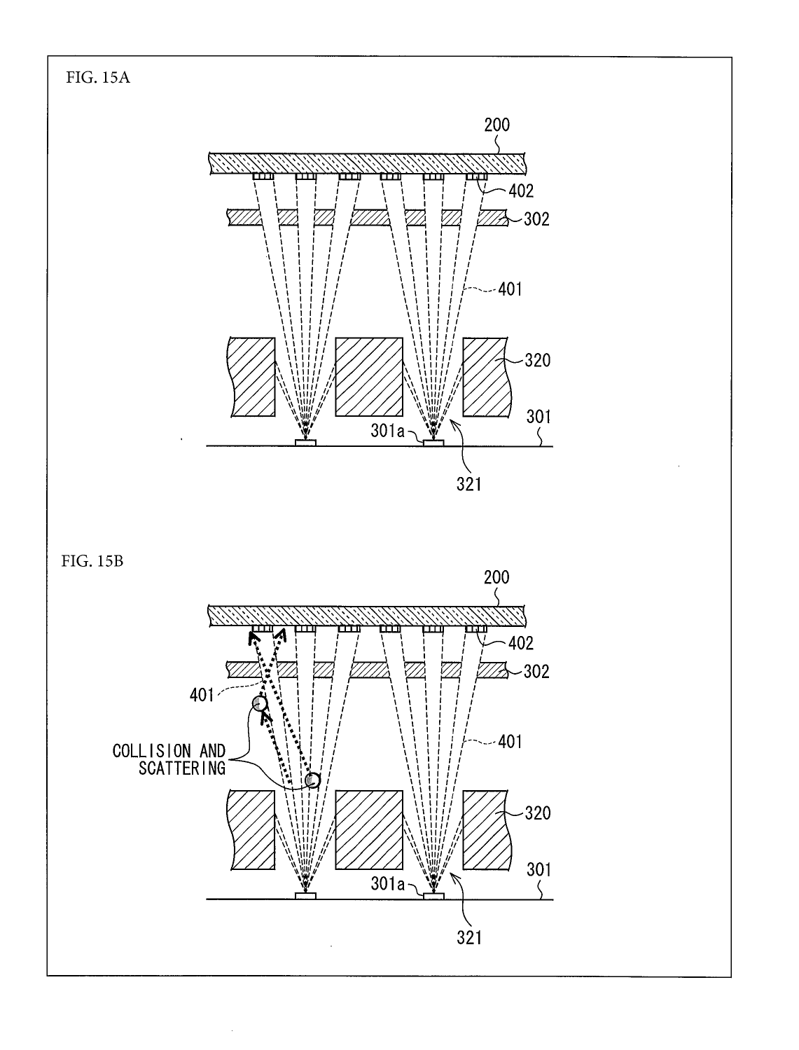

Embodiment 3 is described below with reference to FIGS. 12 and 13.

Embodiment 3 mainly describes differences from Embodiments 1 and 2. Note that members that have identical functions to those of Embodiments 1 and 2 are given identical reference numerals, and are not explained repeatedly.

FIG. 12 is a perspective view schematically illustrating, together with a film formation target substrate 200, a configuration of a substantial part of a vapor deposition unit 1 of a vapor deposition device 100 in accordance with Embodiment 3.

FIG. 13 is a substantial part plan view schematically illustrating a configuration of a limiting plate unit in accordance with Embodiment 3. FIG. 13 schematically illustrates first limiting plates 22, second limiting plates 32, and third limiting plates 72 each viewed in a direction perpendicular to a principal surface of a vapor deposition mask 40.

As illustrated in FIGS. 12 and 13, the vapor deposition unit 1 in accordance with Embodiment 3 is identical in configuration to the vapor deposition unit 1 in accordance with Embodiment 1 except that the vapor deposition unit 1 in accordance with Embodiment 3 further includes a third limiting plate unit 70 which is provided between a second limiting plate unit 30 and a vapor deposition mask 40 and limits angles at which vapor deposition particles 401 that have passed through the second limiting plate unit 30 pass through the third limiting plate unit 70.

FIGS. 12 and 13 each show, an example, a case where the third limiting plate unit 70 is provided between the second limiting plate unit 30 and the vapor deposition mask 40 in the vapor deposition unit 1 in accordance with Embodiment 1. Note, however, that it is needless to say that the third limiting plate unit 70 can be provided between the second limiting plate unit 30 and the vapor deposition mask 40 in the vapor deposition unit 1 in accordance with Embodiment 2.

The third limiting plate unit 70 includes a third limiting plate row 71A of a plurality of third limiting plates 72 and a third limiting plate row 71B of a plurality of third limiting plates 72.

The third limiting plate rows 71A and 71B are provided along the X axis so as to be spaced from each other in the Y axis direction.

The plurality of third limiting plates 72 of each of the third limiting plate rows 71A and 71B are provided in the X axis direction at equal pitches. According to this, when viewed in the direction perpendicular to the principal surface of the vapor deposition mask 40, a limiting plate opening 73 serving as an opening area is provided between the respective third limiting plates 72 that are adjacent to each other in the X axis direction.

The limiting plate openings 73 have a pitch that is larger than that of a plurality of mask openings 41. When viewed in the direction perpendicular to the principal surface of the vapor deposition mask 40, the plurality of mask openings 41 are provided between the third limiting plates 72 that are adjacent to each other in the X axis direction.

The first limiting plates 22 and the third limiting plates 72 each have principal surfaces that are each a YZ plane. Meanwhile, the second limiting plates 32 each have principal surfaces that are each an XZ plane. The third limiting plates 72 are provided so as to be perpendicular to the principal surface of the vapor deposition mask 40. Thus, the third limiting plates 72 are provided so that their front and back surfaces, which serve as the principal surfaces, face in a direction perpendicular to a vapor deposition target surface 201 of the film formation target substrate 200 and the principal surfaces are adjacent to each other in the X axis direction.

The third limiting plates 72 are provided so as not to be parallel to the second limiting plates 32 in a single YZ plane.

According to Embodiment 3, the third limiting plates are made of respective plate members having an identical size. Note, however, that the third limiting plates 72 do not need be identical in size to the first limiting plates 22 and the second limiting plates 32. According to Embodiment 3, the third limiting plates 72 have, for example, a quadrilateral shape. Note, however, that a shape of the third limiting plates 72 is not limited this. The third limiting plates 72 can have, for example, a rectangular shape as in the case of the first limiting plates 22.

According to Embodiment 3, the vapor deposition particles 401 injected from a vapor deposition source 10 pass through a first limiting plate unit 20 and then pass through the second limiting plate unit 30. Thereafter, the vapor deposition particles 401 pass through the third limiting plate unit 70, enter the plurality of mask openings 41 provided on the vapor deposition mask 40, and are then vapor-deposited on the film formation target substrate 200.

As in the case of the first limiting plate unit 20 and the second limiting plate unit 30, the third limiting plate unit 70 selectively captures, in accordance with angles at which the vapor deposition particles 401 have entered the third limiting plate unit 70, the vapor deposition particles 401 that have entered the third limiting plate unit 70.

As in the case of the first limiting plates 22 and the second limiting plates 32, the third limiting plates 72 which are unheated or are cooled by a heat exchanger (not illustrated) so as to block obliquely scattering vapor deposition components. This causes the third limiting plates 72 to have a lower temperature than injection holes 11 of the vapor deposition source 10 (more strictly speaking, a temperature lower than a vapor deposition particle generation temperature at which a vapor deposition material turns into gas).

Thus, the third limiting plate unit 70 can appropriately include a cooling mechanism (not illustrated) for cooling the third limiting plates 72.

Note that the third limiting plates 72 can be fixed by a method similar to the method by which the first limiting plates 22 and the second limiting plates 32 are fixed. That is, Embodiment 3 can also use a method similar to the method by which the first limiting plates 22 and the second limiting plates 32 are fixed as illustrated in FIGS. 4 through 6.

According to Embodiment 3, vapor deposition flows in which the vapor deposition components which slightly decrease in directivity have been blocked by the second limiting plate unit 30 enter the third limiting plate unit 70. In this case, the third limiting plate unit 70 allows the third limiting plates 72 to block the vapor deposition components having lower directivity. The third limiting plate unit 70 also allows the third limiting plates 72 to block the vapor deposition components which have low directivity and have not been blocked by the second limiting plates 32.

Meanwhile, among the vapor deposition components which have low directivity and have not been blocked by the second limiting plates 32, vapor deposition components that have been changed, by repeated scattering and collision of particles, to vapor deposition components having high directivity can be used as a vapor-deposited film 402 without being blocked by the third limiting plates 72.

As described earlier, the third limiting plate unit 70 further provided downstream of the second limiting plate unit 30 makes it possible to separately provide functions to the respective limiting plate units. This makes it unnecessary for the second limiting plates 32 to be designed to have a complicated shape or arrangement.

Further, as described earlier, in a case where the plurality of limiting plate units provided so as to constitute respective of the plurality of stages are provided, particularly in a case where the plurality of limiting plate units provided so as to constitute respective of the plurality of stages are provided between the first limiting plate unit 20 and the vapor deposition mask 40 as described earlier, both prevention of a vapor deposition blur and an improvement in material utilization efficiency can be easily and surely achieved without (i) the fear that material utilization efficiency is reduced while the vapor deposition blur can be prevented or (ii) the need to sacrifice prevention of the vapor deposition blur so as to avoid a reduction in material utilization efficiency.

According to Embodiment 3, in a case where the third limiting plate unit 70 is provided downstream of the second limiting plate unit 30, it is possible to block the vapor deposition components having low directivity, including vapor deposition components closer to or completely parallel to the X axis. That is, according to Embodiment 3, in a case where the third limiting plates 72 are completely parallel to the Y axis as described earlier, it is possible to also block the vapor deposition components completely parallel to the X axis.

As described above, in a case where the uppermost (i.e., most downstream side) limiting plate unit that is included in the plurality of limiting plate units provided so as to constitute respective of the plurality of stages and that is the closest to the vapor deposition mask 40 is provided with the third limiting plate unit 70 including the third limiting plates 72 parallel to the Y axis, it is possible for the vapor deposition particles 401 in which the vapor deposition components having low directivity have been eventually eliminated to enter the mask openings 41 of the vapor deposition mask 40.

As illustrated in FIG. 13, Embodiment 3, which has graphically shown, as an example, a case where the third limiting plates 72 are provided so as to overlap with the first limiting plates 22, is not limited to this.

Note, however, that, since the vapor deposition components having low directivity are blocked by the first limiting plate unit 20 and the second limiting plate unit 30, many vapor deposition components having high directivity pass through the third limiting plate unit 70. Thus, in a case where the third limiting plates 72 are provided above limiting plate openings 23 provided between the first limiting plates 22, the vapor deposition components that have high directivity and have been controlled by the first limiting plate unit 20 and the second limiting plate unit 30 may also be blocked by the third limiting plates 72. This makes it desirable to provide the third limiting plates 72 above the first limiting plates 22.

As illustrated in FIG. 12, Embodiment 3 has graphically shown, as an example, a case where the vapor deposition source 10, the first limiting plate unit 20, the second limiting plate unit 30, the third limiting plate unit 70, and the vapor deposition mask 40 are provided so as to be spaced from each other. Note, however, that the vapor deposition source 10, the first limiting plate unit 20, the second limiting plate unit 30, the third limiting plate unit 70, and the vapor deposition mask 40 can be provided so as to be spaced from each other, or be in contact or be integrated with each other. Note that advantages and disadvantages identical to those described in Embodiment 1 are brought in this case.

Embodiment 3 has shown, as an example, a case where the limiting plate units are provided so as to constitute respective of three stages. Note, however, that the limiting plate units can be provided so as to constitute respective of four or more stages. Also in such a case, limiting plates of the limiting plate units do not need to have an identical shape or arrangement but can be provided in accordance with expected vapor deposition distribution.

A vapor deposition unit 1 in accordance with Aspect 1 of the present invention includes: a vapor deposition mask 40; a vapor deposition source 10 for injecting vapor deposition particles 401 toward the vapor deposition mask 40; and a plurality of limiting plate units provided so as to constitute respective of a plurality of stages, the plurality of limiting plate units including at least a first limiting plate unit 20 and a second limiting plate unit 30, and the plurality of limiting plate units being provided between the vapor deposition mask 40 and the vapor deposition source 10 and limiting angles at which the vapor deposition particles 401 pass through the plurality of limiting plate units, the first limiting plate unit 20 including a first limiting plate row 21 of a plurality of first limiting plates 22 which, when viewed in a direction (a Z axis direction) perpendicular to a principal surface of the vapor deposition mask 40, are provided so as to be spaced from each other in a first direction (an X axis direction) and be parallel to each other, the second limiting plate unit 30 being provided between the first limiting plate unit 20 and the vapor deposition mask 40 and including a plurality of second limiting plates 32, and when viewed in the direction perpendicular to the principal surface of the vapor deposition mask 40, the plurality of second limiting plates 32 extending in a direction intersecting with a second direction (a Y axis direction) perpendicular to the first direction.

According to this, the vapor deposition unit 1 is configured such that end surfaces 32a of the plurality of second limiting plates 32 intersect with at least one of (i) end surfaces 22a of the plurality of first limiting plates 22 of a first limiting plate row 21 and (ii) an opening area (limiting plate openings 23) provided between the plurality of first limiting plates 22.

The configuration allows vapor deposition components (the vapor deposition particles 401) having low directivity to be blocked by the plurality of second limiting plates 32 even in a case where the vapor deposition flows whose directivity has been improved by the plurality of first limiting plates 22 deteriorate (have a so-called isotropic distribution) after passing through the opening area (the limiting plate openings 23) provided between the plurality of first limiting plates 22.

Thus, the vapor deposition particles 401 that have passed through the second limiting plate unit 30 pass through the vapor deposition mask 40 while maintaining high directivity, and are then vapor-deposited on a film formation target substrate 200. This allows a reduction in vapor deposition blur and makes it possible to form a high-definition vapor-deposited film pattern having an extremely small amount of vapor deposition blur.

The vapor deposition unit 1, which includes, on a vapor deposition route (in the Z axis direction), a plurality of limiting plate units provided so as to constitute respective of a plurality of stages, can efficiently block, in accordance with a distribution of vapor deposition flows, only a distribution of vapor deposition flows causing a vapor deposition blur. This reduces a material to be wasted on the limiting plates as in the limiting plates having a longer length when viewed in the direction perpendicular to the principal surface of the vapor deposition mask 40.

Thus, the vapor deposition unit 1 makes it possible to (i) reduce a vapor deposition blur occurring when the vapor deposition rate is high and (ii) further enhance material utilization efficiency as compared with a conventional technique. This allows a higher yield and higher productivity.

In Aspect 2 of the present invention, the vapor deposition unit 1 in accordance with Aspect 1 of the present invention is preferably configured such the plurality of first limiting plates 22 and the plurality of second limiting plates 32 are provided so as to be perpendicular to the principal surface of the vapor deposition mask 40.

In this case, the plurality of first limiting plates 22 and the plurality of second limiting plates 32 can be each easily arranged and are each not likely to block the vapor deposition particles having high directivity.

In Aspect 3 of the present invention, the vapor deposition unit 1 in accordance with Aspect 1 or 2 of the present invention is preferably configured such that, when viewed in the direction perpendicular to the principal surface of the vapor deposition mask 40, the plurality of first limiting plates 22 and the plurality of second limiting plates 32 extend in a direction in which end surfaces of the plurality of first limiting plates 22 and end surfaces of the plurality of second limiting plates 32 are orthogonal to each other.

That is, the second limiting plate unit 30 preferably includes a second limiting plate row 31 of the plurality of second limiting plates 32 which, when viewed in the direction perpendicular to the principal surface of the vapor deposition mask 40, are provided so as to spaced from each other in the second direction perpendicular to the first direction.

According to the configuration, the plurality of second limiting plates 32 can be easily provided and the vapor deposition components having low directivity can be blocked by the plurality of second limiting plates 32 even in a case where the vapor deposition flows whose directivity has been improved by the plurality of first limiting plates 22 deteriorate after passing through the opening area (the limiting plate openings 23) provided between the plurality of first limiting plates 22.

In Aspect 4 of the present invention, the vapor deposition unit 1 in accordance with Aspect 1 or 2 of the present invention is preferably configured such that, when viewed in the direction perpendicular to the principal surface of the vapor deposition mask 40, the plurality of second limiting plates 32 are provided so as to be closer to the first direction.

That is, the plurality of second limiting plates 32 can be provided so that, when viewed in the direction perpendicular to the principal surface of the vapor deposition mask 40, (i) the plurality of second limiting plates 32 as a whole are closer to the first direction or (ii) bend lines of the plurality of second limiting plates 32 are closer to the first direction.

The vapor deposition particles 401 which have lower directivity are more likely to fly closer to the X axis. Thus, in a case where the vapor deposition particles 401 massively decrease in directivity, the vapor deposition particles 401 having low directivity are preferably captured by the plurality of second limiting plates 32 which are provided so as to be closer to the first direction when viewed in the direction perpendicular to the principal surface of the vapor deposition mask 40.

According to the configuration, it is possible to also block the vapor deposition particles 401 that are closer to the first direction. Thus, it is possible to limit scattering of vapor deposition flows having high kinetic energy when the vapor deposition rate is higher. This makes it possible to reduce the vapor deposition blur even in a case where the vapor deposition particles 401 massively decrease in directivity due to collision and scattering of the vapor deposition particles 401.

In Aspect 5 of the present invention, the vapor deposition unit 1 in accordance with Aspect 4 of the present invention is preferably configured such that the plurality of second limiting plates 32 each have at least one bend point when viewed in the direction perpendicular to the principal surface of the vapor deposition mask 40.

As described above, the plurality of second limiting plates 32, which are bent, are continuously provided in the second direction so as to be closer to the first direction.

Thus, it is possible to limit scattering of vapor deposition flows having high kinetic energy when the vapor deposition rate is higher. This makes it possible to reduce the vapor deposition blur even in a case where the vapor deposition particles 401 massively decrease in directivity due to collision and scattering of the vapor deposition particles 401.

In Aspect 6 of the present invention, the vapor deposition unit 1 in accordance with Aspect 5 of the present invention is preferably configured such that the end surfaces of the plurality of second limiting plates 32 each have a plurality of bend points when viewed in the direction perpendicular to the principal surface of the vapor deposition mask 40.

That is, the plurality of second limiting plates 32 can have, for example, a zigzag shape.

A larger number of bend points cause the second limiting plates 32 to block more vapor deposition components (vapor deposition particles 401) having low directivity, so that the vapor deposition blur can be further reduced.

The vapor deposition unit 1 in accordance with Aspect 5 or 6 of the present invention can be configured such that, when viewed in the direction perpendicular to the principal surface of the vapor deposition mask 40, the plurality of second limiting plates 32 are provided only in a region near injection holes 11 of the vapor deposition source 10.

Thus, in Aspect 7 of the present invention, the vapor deposition unit 1 in accordance with Aspect 5 or 6 of the present invention can be configured such that, when viewed in the direction perpendicular to the principal surface of the vapor deposition mask 40, the plurality of second limiting plates 32 are provided, for example, only in a region overlapping with a row of the injection holes 11 of the vapor deposition source 10 which injection holes 11 are provided in the second direction.

In Aspect 8 of the present invention, the vapor deposition unit 1 in accordance with any one of Aspects 5 through 7 of the present invention can be configured such that, when viewed in the direction perpendicular to the principal surface of the vapor deposition mask 40, (i) the injection holes 11 of the vapor deposition source 10 are provided above respective central parts of the limiting plate openings 23 provided between the plurality of first limiting plates 22 and (ii) the plurality of second limiting plates 32 are provided only in a region in which central parts of the plurality of first limiting plates 22 are located.

In Aspect 9 of the present invention, the vapor deposition unit 1 in accordance with Aspect 6 of the present invention is preferably configured such that, when viewed in the direction perpendicular to the principal surface of the vapor deposition mask 40, the plurality of second limiting plates 32 each have (i) a bend angle that is relatively small in a region (e.g., a region P1 above a central part of a limiting plate opening 23) which is relatively close to an injection hole 11 of the vapor deposition source 10 and (ii) a bend angle that is relatively great in a region (e.g., regions P2 and P3 above the limiting plate opening 23 and closer to both ends of the limiting plate opening 23 in the Y axis direction) which is relatively distant from the injection hole 11.

In Aspect 10 of the present invention, the vapor deposition unit 1 in accordance with Aspect 9 of the present invention is preferably configured such that, the plurality of second limiting plates 32 each viewed in the direction perpendicular to the principal surface of the vapor deposition mask 40 are provided to have a greater bend angle in the region which is more distant from the injection hole 11 of the vapor deposition source 10.

The vapor deposition particles 401 are highly likely to collide with each other in a region near and above injection holes 11, in which region vapor deposition density is high. This easily causes a deterioration in directivity of the vapor deposition particles 401. Meanwhile, since the vapor deposition density decreases in a region more distant from the injection holes 11, the vapor deposition particles 401 are less likely to deteriorate in directivity.

Thus, according to the configurations of Aspects 7 through 10, it is possible (i) to prevent or reduce blocking of the vapor deposition particles 401 having high directivity and (ii) efficiently block the vapor deposition particles 401 having low directivity and flying closer to the X axis direction.

In Aspect 11 of the present invention, the vapor deposition unit 1 in accordance with Aspect 4 of the present invention is preferably configured such that the plurality of second limiting plates 32 intersect with each other when viewed in the direction perpendicular to the principal surface of the vapor deposition mask 40.

According to the configuration, the plurality of second limiting plates 32 block more vapor deposition components having low directivity, so that the vapor deposition blur is further reduced.

In Aspect 12 of the present invention, the vapor deposition unit 1 in accordance with any one of Aspects 1 through 11 of the present invention is preferably configured such that, when viewed in the direction perpendicular to the principal surface of the vapor deposition mask, the plurality of second limiting plates are continuously provided in the first direction so as to extend across the plurality of first limiting plates.

According to the vapor deposition unit, the plurality of second limiting plates can be easily provided.

In Aspect 13 of the present invention, the vapor deposition unit 1 in accordance with any one of Aspects 1 through 12 of the present invention is preferably configured such that the plurality of second limiting plates 32 are provided in the first direction and the second direction when viewed in the direction perpendicular to the principal surface of the vapor deposition mask 40.

According to the configuration, the plurality of second limiting plates 32 can be made of a combination of small parts. This makes it possible to carry out (i) maintenance such as replacement of the limiting plates and (ii) precise adjustment in accordance with the nozzle distribution and the vapor deposition distribution.

In Aspect 14 of the present invention, the vapor deposition unit 1 in accordance with any one of Aspects 1 through 13 of the present invention is preferably configured such that the plurality of first limiting plates 22 and the plurality of second limiting plates 32 are provided so as to be spaced from each other.

According to the configuration, it is possible to utilize an opportunity for the vapor deposition particles 401 having lower directivity after passing through the space between the plurality of respective first limiting plates 22 to have higher directivity. Thus, it is possible to prevent a reduction in material utilization efficiency.

In Aspect 15 of the present invention, the vapor deposition unit 1 in accordance with any one of Aspects 1 through 14 of the present invention is preferably configured such that the plurality of first limiting plates and the plurality of second limiting plates 32 are provided so as be in contact with each other.

The configuration, which makes it possible to capture, without fail, the vapor deposition particles 401 that have passed through a space between the respective plurality of first limiting plates 22 and have low directivity, has an advantage in that a vapor deposition blur is less likely to occur. Further, it is possible to extremely accurately align the plurality of first limiting plates 22 with the respective plurality of second limiting plates 32 by, for example, a pin alignment. For example, the plurality of first limiting plates 22 provided with a cooling mechanism allow the plurality of second limiting plates 32 to be cooled by the cooling mechanism provided for the plurality of first limiting plates 22 without the need to separately provide the plurality of second limiting plates with a cooling mechanism. Thus, it is possible to prevent reevaporation of the captured vapor deposition particles 401 with a simple configuration.

In Aspect 16 of the present invention, the vapor deposition unit 1 in accordance with any one of Aspects 1 through 15 of the present invention is preferably configured such that the plurality of limiting plate units provided so as to constitute respective of the plurality of stages further include a third limiting plate unit 70 which is provided between the second limiting plate unit 30 and the vapor deposition mask 40 and limits angles at which the vapor deposition particles 401 that have passed through the second limiting plate unit 30 pass through the third limiting plate unit 70; and the third limiting plate unit 70 including a third limiting plate row 71 of a plurality of third limiting plates 72 which, when viewed in the direction perpendicular to the main surface of the vapor deposition mask 40, are provided so as to at least be spaced from each other in the first direction and be parallel to each other.

According to the configuration, vapor deposition flows in which the vapor deposition components which slightly decrease in directivity have been blocked by the second limiting plate unit 30 enter the third limiting plate unit 70. In this case, the third limiting plate unit 70 allows the plurality of third limiting plates 72 to block the vapor deposition components having lower directivity. The third limiting plate unit 70 also allows the plurality of third limiting plates 72 to block the vapor deposition components which have low directivity and have not been blocked by the plurality of second limiting plates 32.

Meanwhile, among the vapor deposition components which have low directivity and have not been blocked by the plurality of second limiting plates 32, vapor deposition components that have been changed, by repeated scattering and collision of vapor deposition particles, to vapor deposition components having high directivity can be used as a vapor-deposited film 402 without being blocked by the plurality of third limiting plates 72.

The third limiting plate unit 70 further provided downstream of the second limiting plate unit 30 makes it possible to separately provide functions to the respective limiting plate units. This makes it possible to block the vapor deposition components having low directivity, including vapor deposition components closer to or completely parallel to the X axis, without the need to design the plurality of second limiting plates 32 to have a complicated shape or arrangement. Thus, both prevention of a vapor deposition blur and an improvement in material utilization efficiency can be easily achieved without fail.

In Aspect 17 of the present invention, the vapor deposition unit 1 in accordance with any one of Aspects 1 through 16 of the present invention is preferably configured such that, when viewed in the direction perpendicular to the principal surface of the vapor deposition mask 40, the plurality of second limiting plates 32 each have (i) an arrangement density that is relatively high in a region (e.g., a region P1 above a central part of a limiting plate opening 23) which is relatively close to an injection hole 11 of the vapor deposition source 10 and (ii) an arrangement density that is relatively low in a region (e.g., regions P2 and P3 above the limiting plate opening 23 and closer to both ends of the limiting plate opening 23 in the Y axis direction) which is relatively distant from the injection hole 11.

In Aspect 18 of the present invention, the vapor deposition unit 1 in accordance with Aspect 17 of the present invention is preferably configured such that the plurality of second limiting plates 32 each viewed in the direction perpendicular to the principal surface of the vapor deposition mask 40 are provided to have a lower arrangement density in the region which is more distant from the injection hole 11 of the vapor deposition source 10.

According to the configuration of Aspect 17 or 18, it is possible (i) to prevent or reduce blocking of the vapor deposition particles 401 having high directivity and (ii) efficiently block the vapor deposition particles 401 having low directivity and flying closer to the X axis direction.

The vapor deposition device 100 in accordance with Aspect 19 of the present invention is configured such that the vapor deposition unit 1 recited in any one of Aspects 1 through 18; and a moving device (a substrate moving device 103 or a vapor deposition unit moving device 104) for, in a state in which the vapor deposition mask 40 of the vapor deposition unit 1 and a film formation target substrate 200 are provided so as to face each other, moving one of the vapor deposition unit 1 and the film formation target substrate 200 with respect to the other so that the second direction is a scanning direction, the vapor deposition mask 40 having a smaller width in the second direction than the film formation target substrate 200, while carrying out scanning in the second direction, the vapor deposition device 100 vapor-depositing, on the film formation target substrate 200 via (i) the plurality of limiting plate units provided so as to constitute respective of the plurality of stages and (ii) an opening of the vapor deposition mask 40, the vapor deposition particles 401 injected from the vapor deposition source 10.

Thus, the vapor deposition device 100 makes it possible to (i) reduce a vapor deposition blur occurring when the vapor deposition rate is high and (ii) further enhance material utilization efficiency as compared with a conventional technique. This allows a higher yield and higher productivity.

The present invention is not limited to the embodiments, but can be altered by a skilled person in the art within the scope of the claims. An embodiment derived from a proper combination of technical means disclosed in respective different embodiments is also encompassed in the technical scope of the present invention. Further, a new technical feature can be formed by combining technical means disclosed in the embodiments.

The present invention can be suitably used for (i) a vapor deposition unit that carries out vapor deposition while carrying out scanning by moving a film formation target substrate and a vapor deposition unit with respect to each other and that is used for scan vapor deposition using a scanning system and (ii) a vapor deposition device that uses such a vapor deposition unit to form a film having a predetermined pattern. In particular, the vapor deposition unit and the vapor deposition device of the present invention can be suitably used in, for example, a device for and a method for manufacturing an organic EL display device, which are used in a film formation process such as a selective formation of organic layers in the organic EL display device.

### REFERENCE SIGNS LIST

1: Vapor deposition unit

10: Vapor deposition source

11: Injection hole

20: First limiting plate unit

21: First limiting plate row

22, 22A, and 22B: First limiting plate

22a: End surface

23, 23A, and 23B: Limiting plate opening (opening area)

24: First holding member

25: Second holding member

26: Holding body

27: Supporting section

28: Gap

30: Second limiting plate unit

31: Second limiting plate row

32: Second limiting plate

32a: End surface

33: Limiting plate opening (opening area)

34: First holding member

35: Second holding member

36: Holding body

37: Supporting section

40: Vapor deposition mask

41: Mask opening

42: Alignment marker

50: Holder

51: Sliding device

52: Supporting member

53: Tension mechanism

60: Deposition preventing plate

70: Third limiting plate unit

71, 71A, and 71B: Third limiting plate row

72: Third limiting plate

73: Limiting plate opening (opening area)

100: Vapor deposition device

101: Vacuum chamber

102: Substrate holder

103: Substrate moving device

104: Vapor deposition unit moving device

105: Image sensor

200: Film formation target substrate

201: Vapor deposition target surface

202: Alignment marker

401: Vapor deposition particles

402: Vapor-deposited film

1. A vapor deposition unit comprising:
a vapor deposition mask;
a vapor deposition source for injecting vapor deposition particles toward the vapor deposition mask; and
a plurality of limiting plate units provided so as to constitute respective of a plurality of stages, the plurality of limiting plate units including at least a first limiting plate unit and a second limiting plate unit, and the plurality of limiting plate units being provided between the vapor deposition mask and the vapor deposition source and limiting angles at which the vapor deposition particles pass through the plurality of limiting plate units,
the first limiting plate unit including a first limiting plate row of a plurality of first limiting plates which, when viewed in a direction perpendicular to a principal surface of the vapor deposition mask, are provided so as to be spaced from each other in a first direction and be parallel to each other,
the second limiting plate unit being provided between the first limiting plate unit and the vapor deposition mask and including a plurality of second limiting plates, and
when viewed in the direction perpendicular to the principal surface of the vapor deposition mask, the plurality of second limiting plates extending in a direction intersecting with a second direction perpendicular to the first direction.

2. The vapor deposition unit as set forth in claim 1, wherein the plurality of first limiting plates and the plurality of second limiting plates are provided so as to be perpendicular to the principal surface of the vapor deposition mask.

3. The vapor deposition unit as set forth in claim 1, wherein, when viewed in the direction perpendicular to the principal surface of the vapor deposition mask, the plurality of first limiting plates and the plurality of second limiting plates extend in a direction in which end surfaces of the plurality of first limiting plates and end surfaces of the plurality of second limiting plates are orthogonal to each other.

4. The vapor deposition unit as set forth in claim 1, wherein, when viewed in the direction perpendicular to the principal surface of the vapor deposition mask, the plurality of second limiting plates are provided so as to be closer to the first direction.

5. The vapor deposition unit as set forth in claim 4, wherein the plurality of second limiting plates each have at least one bend point when viewed in the direction perpendicular to the principal surface of the vapor deposition mask.

6. The vapor deposition unit as set forth in claim 5, wherein the end surfaces of the plurality of second limiting plates each have a plurality of bend points when viewed in the direction perpendicular to the principal surface of the vapor deposition mask.

7. The vapor deposition unit as set forth in claim 6, wherein, when viewed in the direction perpendicular to the principal surface of the vapor deposition mask, the plurality of second limiting plates each have (i) a bend angle that is relatively small in a region which is relatively close to an injection hole of the vapor deposition source and (ii) a bend angle that is relatively great in a region which is relatively distant from the injection hole.

8. The vapor deposition unit as set forth in claim 4, wherein the plurality of second limiting plates intersect with each other when viewed in the direction perpendicular to the principal surface of the vapor deposition mask.

9. The vapor deposition unit as set forth in claim 1, wherein, when viewed in the direction perpendicular to the principal surface of the vapor deposition mask, the plurality of second limiting plates are continuously provided in the first direction so as to extend across the plurality of first limiting plates.

10. The vapor deposition unit as set forth in claim 1, wherein the plurality of second limiting plates are provided in the first direction and the second direction when viewed in the direction perpendicular to the principal surface of the vapor deposition mask.

11. The vapor deposition unit as set forth in claim 1, wherein the plurality of first limiting plates and the plurality of second limiting plates are provided so as to be spaced from each other.

12. The vapor deposition unit as set forth in claim 1, wherein the plurality of first limiting plates and the plurality of second limiting plates are provided so as be in contact with each other.

13. The vapor deposition unit as set forth in claim 1, wherein:
the plurality of limiting plate units provided so as to constitute respective of the plurality of stages further include a third limiting plate unit which is provided between the second limiting plate unit and the vapor deposition mask and limits angles at which the vapor deposition particles that have passed through the second limiting plate unit pass through the third limiting plate unit; and
the third limiting plate unit including a third limiting plate row of a plurality of third limiting plates which, when viewed in the direction perpendicular to the main surface of the vapor deposition mask, are provided so as to at least be spaced from each other in the first direction and be parallel to each other.

14. The vapor deposition unit as set forth in claim 1, wherein, when viewed in the direction perpendicular to the principal surface of the vapor deposition mask, the plurality of second limiting plates each have (i) an arrangement density that is relatively high in a region which is relatively close to an injection hole of the vapor deposition source and (ii) an arrangement density that is relatively low in a region which is relatively distant from the injection hole.

15. A vapor deposition device comprising:
the vapor deposition unit recited in claim 1; and
a moving device for, in a state in which the vapor deposition mask of the vapor deposition unit and a film formation target substrate are provided so as to face each other, moving one of the vapor deposition unit and the film formation target substrate with respect to the other so that the second direction is a scanning direction,
the vapor deposition mask having a smaller width in the second direction than the film formation target substrate,
while carrying out scanning in the second direction, the vapor deposition device vapor-depositing, on the film formation target substrate via (i) the plurality of limiting plate units provided so as to constitute respective of the plurality of stages and (ii) an opening of the vapor deposition mask, the vapor deposition particles injected from the vapor deposition source.

16. A vapor deposition method carried out by use of a vapor deposition device including: (i) a vapor deposition unit including: the vapor deposition mask; a vapor deposition source for injecting vapor deposition particles toward the vapor deposition mask; and a plurality of limiting plate units provided so as to constitute respective of a plurality of stages, the plurality of limiting plate units including at least a first limiting plate unit and a second limiting plate unit, and the plurality of limiting plate units being provided between the vapor deposition mask and the vapor deposition source and limiting angles at which the vapor deposition particles pass through the plurality of limiting plate units, the first limiting plate unit including a first limiting plate row of a plurality of first limiting plates which, when viewed in a direction perpendicular to a principal surface of the vapor deposition mask, are provided so as to be spaced from each other in a first direction and be parallel to each other, the second limiting plate unit being provided between the first limiting plate unit and the vapor deposition mask and including a plurality of second limiting plates, when viewed in the direction perpendicular to the principal surface of the vapor deposition mask, the plurality of second limiting plates extending in a direction intersecting with a second direction perpendicular to the first direction, and the vapor deposition mask having a smaller width in the second direction than a film formation target substrate; and (ii) a moving device for, in a state in which the vapor deposition mask of the vapor deposition unit and the film formation target substrate are provided so as to face each other, moving one of the vapor deposition unit and the film formation target substrate with respect to the other so that the second direction is a scanning direction,
said vapor deposition method comprising:
(a) providing the vapor deposition mask of the vapor deposition device and the film formation target substrate so that the vapor deposition mask and the film formation target substrate face each other; and
(b) while scanning the film formation target substrate in the second direction by causing the movement device to move one of the vapor deposition unit and the film formation target substrate with respect to the other so that the second direction is the scanning direction, vapor-depositing, on the film formation target substrate via (i) the plurality of limiting plate units provided so as to constitute respective of the plurality of stages and (ii) an opening of the vapor deposition mask, the vapor deposition particles injected from the vapor deposition source.
